(19) United States
(12) Patent Application Publication
(10) Pub. No.: US 2012/0018733 A1
(43) Pub. Date: Jan. 26, 2012

(54) Thin Film Solar Cells And Other Devices, Systems And Methods Of Fabricating Same, And Products Produced By Processes Thereof

(76) Inventor: Venkatraman Prabhakar, Pleasanton, CA (US)

(21) Appl. No.: 13/190,457

(22) Filed: Jul. 25, 2011

Related U.S. Application Data
(60) Provisional application No. 61/367,366, filed on Jul. 23, 2010.

(51) Int. Cl. H01L 29/04; H01L 21/20; H01L 21/268

(52) U.S. Cl. 257/75; 438/487; 438/486; 257/E29.003; 257/E21.133; 257/E21.134

(57) ABSTRACT

Systems, methods, devices, and products of processes consistent with the innovations herein relate to thin-film solar cells and other devices. In one exemplary implementation, there is provided a thin film device.

### CROSS-REFERENCE TO RELATED APPLICATION(S)

This application claims benefit and priority of U.S. provisional patent application No. 61/367,366, filed Jul. 23, 2010, which is incorporated herein by reference in entirety.

### BACKGROUND

### Description of Related Information

The literature discusses a wide variety of solar cells. The most dominant solar cells in the market place are the crystalline silicon solar cells which are made from wafers which are 150 μm thick. In contrast, thin film solar cells are made of thinner layers (25 μm or less), usually on a substrate such as glass. Glass is the most common although, in some instances when certain limitations are met, steel and plastic may also be used. Thin film solar cells are most commonly made of amorphous silicon, CdTe and CIGS (Copper/Indium/Gallium/Selenide). Thin film solar cells have lower efficiency than crystalline silicon solar cells due to the poorer film quality/crystallinity. Thus, the lower cost of manufacture and lower material usage of thin films is partially negated by the low efficiencies achieved. Thin film solar cells are generally made with a single deposition of the film, at present. There are several approaches to deposit the layers with PECVD (plasma enhanced chemical vapor deposition) being preferred approach. Other methods such as HWCVD (hot-wire chemical vapor deposition) are also possible. For thin film silicon solar cells several groups have been doing a single deposition using epitaxy from the gas phase. One drawback of epitaxy is the high temperatures required which precludes use of cheap substrates such as borosilicate or soda-lime glass. The epitaxy approach has therefore forced several groups to go to ceramic substrates. Drawbacks of ceramic substrates include contamination introduced by metallic impurities which get into the silicon film and degrade the performance.

Some attempt has been made in the production of thin film cells to provide/utilize both a thin layer and a thick layer at the same time, though always with various drawbacks. For example, the stress in the silicon-layer may cause a variety of issues including peeling of the layer off the substrate. Further, here, various drawbacks must be overcome to achieve efficient use of such layering, such as enabling the thicker layer to adhere well and avoid any peeling issues.

As such, aspects of the present innovations relate to devices including high efficiency thin film solar cells, and fabrication thereof. Exemplary implementations herein may, inter alia, involve features and/or processes related to depositing films in 2 or more steps with a crystallization step in between.

Additionally, solar cells may be characterized by their electrical contacts, such as those with electrical contacts on both the front side and backside of crystalline silicon solar cells. With regard to solar cells, the front is generally considered to be the side from which the sunlight enters the device. In existing devices, the n-doped region (cathode) and p-doped region (anode) are arranged in a vertical manner, front side to backside, and separated by a lightly doped region.

In addition to other drawbacks, solar cells with front-side contacts suffer from “shadowing”, i.e., shadows caused by front side structures that diminish the sunlight that reaches the solar cell to be transformed into electricity. To avoid this problem, existing solar cell fabrication methods sometimes use transparent conductive oxides (TCOs) for front-side contacts. One such transparent conductive oxide is ITO (Indium-Tin-Oxide). Notably, the use of these transparent electrodes involves a trade-off between electrical and optical performance, i.e., a thicker layer will have lower resistance and hence a higher electrical efficiency. However, a thicker layer will also transmit less light into the solar cell and hence create lower optical efficiency. Furthermore, TCO/ITO layers are also very sensitive to moisture an contribute to the degradation of solar cell efficiency and reliability over their 20-30 year lifetime. In addition, backside contact solar cells generally require high quality device layers (e.g. silicon) which have not yet been possible given existing technologies.

With regard to solar cells consisting of crystalline silicon, most devices are formed with front and backside contacts. However, some limited technologies for such full-silicon substrates do utilize contacts on the backside, only. One drawback of these technologies is that they generally require high temperature anneal processes (e.g. 900° C.) to passivate the backside and also to diffuse the dopants into the silicon substrate. Such high temperatures are above the softening point of glass and cannot be used with thin film technologies that utilize glass and plastic substrates. In addition, the purely silicon substrates require a thickness of more than 150 or 200 μm for mechanical stability. This increases the material costs substantially as well as the processing/manufacturing costs, e.g., due to the need for high temperature steps, etc.

As set forth below, one or more additional exemplary aspects of the present inventions may overcome such drawbacks and/or otherwise impart innovations consistent with the systems and methods herein via the provision of backside only contact thin-film solar cells and/or devices.

### BRIEF DESCRIPTION OF THE DRAWINGS

The accompanying drawings, which constitute a part of this specification, illustrate various implementations and aspects of the present invention and, together with the description, explain the principles of the innovations herein. In the drawings:

FIG. 1 is a block diagram of an exemplary implementation of the anti-reflective coating and first silicon layer deposition and crystallization consistent with certain aspects related to the innovations herein.

FIG. 2 is a block diagram of an exemplary implementation of the first layer crystallization including a seed layer consistent with certain aspects related to the innovations herein.

FIG. 3 is a block diagram of an exemplary implementation of the first layer crystallization including a seed layer below the silicon layer consistent with certain aspects related to the innovations herein.

FIG. 4 is a block diagram of an exemplary implementation of second layer deposition and crystallization consistent with certain aspects related to the innovations herein.

FIG. 5 is a flow chart of an exemplary implementation consistent with certain aspects related to the innovations herein.

FIG. 6 is a flow chart of an exemplary implementation including the introduction of dopants and completion of metallization consistent with certain aspects related to the innovations herein.

FIGS. 7A and 7B are flow charts of exemplary implementations of the steps relating to transforming the 1^{st} silicon-containing layer into partially or fully crystalline form consistent with certain aspects related to the innovations herein.

FIG. 8 is a flow chart of an exemplary implementation of depositing and crystallizing the 2^{nd} amorphous/poly silicon-containing layer consistent with certain aspects related to the innovations herein.

FIGS. 9A and 9B are flow charts of different exemplary implementations of doping regions of the crystallized silicon-containing film and metallization to achieve electrical contacts to regions of the crystallized material.

FIG. 10 is a block diagram of an exemplary implementation of a backside contact solar cell consistent with certain aspects related to the innovations herein.

FIG. 11 is a block diagram of an exemplary implementation of a front and back contact solar cell consistent with certain aspects related to the innovations herein.

FIGS. 12A-12C illustrate several views of exemplary thin-film solar cell structures or devices, consistent with aspects related to the innovations herein.

FIG. 12D illustrates another exemplary thin-film solar cell structure/device, consistent with aspects related to the innovations herein.

FIGS. 13A and 13B illustrate exemplary methods related to fabrication of thin-film substrates, consistent with aspects related to the innovations herein.

FIG. 14 illustrates a substrate having a seed layer above an amorphous/poly material layer, receiving laser irradiation for crystallization, consistent with aspects related to the innovations herein.

FIGS. 15A and 15B illustrate exemplary methods related to fabrication of thin-film substrates, consistent with aspects related to the innovations herein.

FIG. 16 illustrates another exemplary method related to fabrication of thin-film substrates, consistent with aspects related to the innovations herein.

FIGS. 17A and 17B illustrate exemplary methods including crystallization of amorphous/poly materials on substrates, consistent with aspects related to the innovations herein.

FIGS. 18A and 18B illustrate exemplary methods including crystallization of amorphous/poly materials on substrates including a coating step, consistent with aspects related to the innovations herein.

FIG. 19 illustrates another exemplary method including crystallization of amorphous/poly materials on a substrate, consistent with aspects related to the innovations herein.

FIGS. 20-24 illustrate further exemplary methods including crystallization of amorphous/poly materials on substrate(s), consistent with aspects related to the innovations herein.

FIGS. 25A and 25B illustrate exemplary methods of rastering or scanning a laser over a substrate, consistent with aspects related to the innovations herein.

FIG. 26 illustrates aspects of an illustrative process applicable to flat panel displays and/or thin film transistors, consistent with aspects of the innovations herein.

### DETAILED DESCRIPTION OF EXEMPLARY IMPLEMENTATIONS

Reference will now be made in detail to the invention, examples of which are illustrated in the accompanying drawings. The implementations set forth in the following description do not represent all implementations consistent with the claimed inventions. Instead, they are merely some examples consistent with certain aspects related to the innovations herein. Wherever possible, the same reference numbers will be used throughout the drawings to refer to the same or like parts.

Systems and methods consistent with some aspects of the inventions herein may include heating or laser anneal to crystallize a first silicon layer on substrates. According to certain aspects of innovations herein, a second layer of silicon may then deposited on the first layer. In some exemplary aspects of the innovations herein, the second layer of silicon is then crystallized using a laser anneal. In certain other implementations, a lamp or a strip heater may be used for the crystallization. With regard to solar cell embodiments, once a the crystallization of the silicon layer on the substrate is achieved, a full solar cell may be fabricated using N+/P+doping or doped layers, contacts and metallization. Flat panel display embodiments and other embodiments are also detailed elsewhere herein.

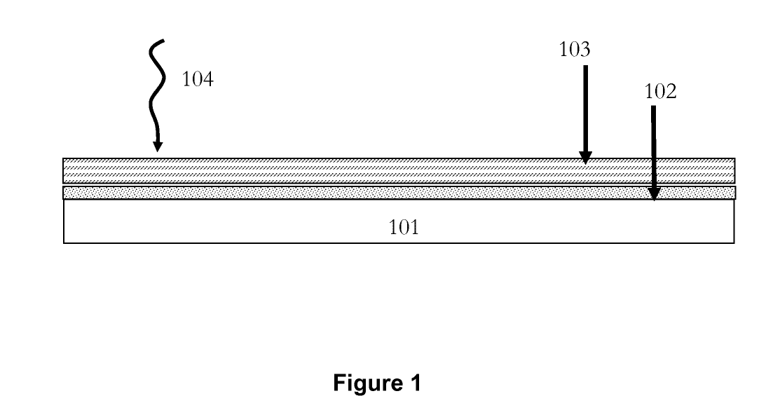

FIG. 1 is a cross-section of an illustrative implementation consistent with one or more aspects of the innovations herein. As shown by way of example in FIG. 1, a substrate 101 such as glass, may be coated with a layer 102. In exemplary implementations of the innovations herein, the layer 102 is a layer of SiN (silicon nitride). The layer 103 is a silicon-containing layer deposited on top of layer 102. In exemplary implementations, this layer 103 may be amorphous silicon. In some implementations the amorphous silicon may have reduced hydrogen content. The reduced hydrogen content may be achieved by adjustment of the deposition method such as using different gases or gas ratios in the deposition chamber and/or by adding a post-deposition anneal to drive out the hydrogen. The layer 103 may be crystallized via laser irradiation 104. In some exemplary implementations, such irradiation may be performed by a solid state laser with a wavelength between 266 nm and 2 μm. In certain exemplary implementations, the laser may be a solid state laser with a wavelength of 515 nm or 532 nm. The laser 104 is shown by way of example to be coming from the top. However, in other implementations, the laser can also be applied from the bottom (through the substrate 101), in certain instances such as when the substrate is transparent to the laser wavelength chosen. The choice of the laser being used from the top or through substrate 101, or via both top and bottom, may be determined as a function of the type of substrate being used and/or other factors including presence of other layers such as anti-reflective coating and the amorphous material thickness, among others.

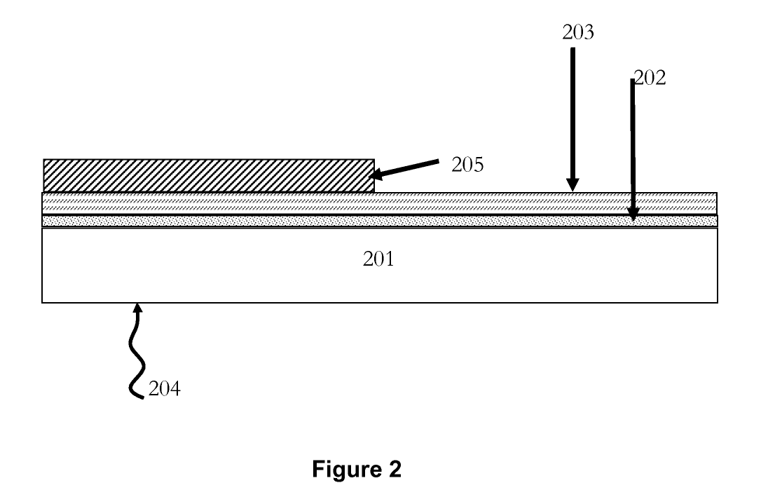

FIG. 2 illustrates alternative implementations of the crystallization of layer 203, consistent with aspects related to the innovations herein. In FIG. 2, the anti-reflective coating 102 is deposited on the substrate 201. An amorphous silicon layer 203 may be deposited on top of layer 202. In an alternative implementation shown in FIG. 2, the seed layer 205 is bonded on top of layer 203. In some implementations, for example, the seed layer 205 may be a crystalline silicon piece. The crystalline silicon piece may be bonded to layer 203 by any desired method such as mechanical, thermal, electrostatic etc. This piece may be thinned down, if desired, to a thickness of approximately 0.05 μm to about 100 μm using any suitable techniques such as cleaving, polishing, etching etc. In FIG. 2, the laser 204 may be used to crystallize the layer 203, using the layer 205 as a seed or template.

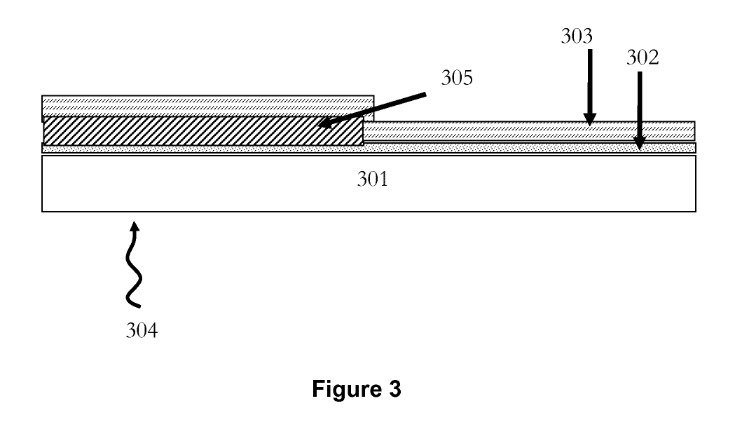

FIG. 3 illustrates further implementations, consistent with aspects of the innovations herein. In FIG. 3, the anti-reflective layer 302 is coated on top of substrate 301 as before. The seed layer 305 is then bonded on top of layer 302, and then the amorphous silicon layer 303 is deposited on top of layer 305 and layer 302. In FIG. 3, the laser 304 may be used to crystallize the layer 303 using layer 305 as a seed. In exemplary implementations, this laser may be a green or UV solid state laser. Other lasers such as excimer lasers may also be used in certain applications.

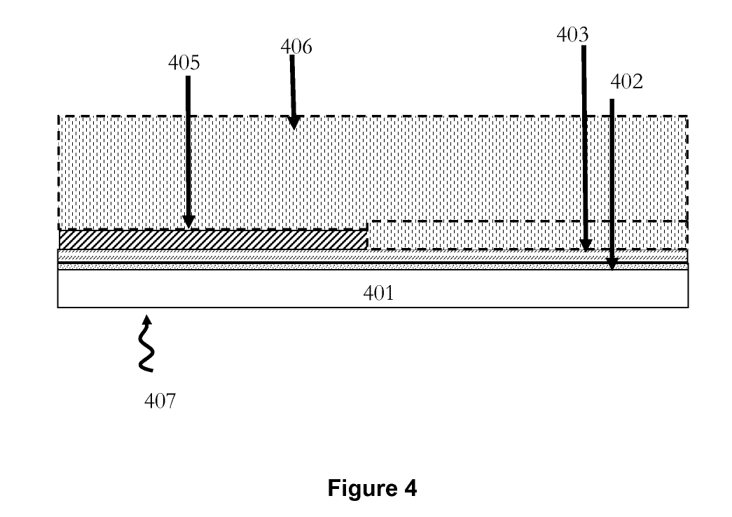

FIG. 4 is a cross-section illustrating an exemplary implementation consistent with one or more aspects of the innovations herein. As shown by way of example in FIG. 4, the substrate 401 is coated with an anti-reflective layer 402 and a silicon containing layer 403. Further, the seed layer 405 may already be bonded on layer 403 and crystallized (as described in FIG. 2) with a laser. As further shown in FIG. 4, a second silicon containing layer 406 may be deposited on top of layer 405 and layer 403. The second silicon containing layer 406 may be amorphous silicon similar to layer 403. In some implementations, the second silicon containing layer 406 may be polysilicon or silicon-germanium (SiGe). In other words, the layer 406 and layer 403 may be the same composition or different compositions. In some implementations, the silicon-containing layer 406 may also be doped during the deposition (in-situ) or after the deposition using either N-type dopants (e.g. Phosphorous, Arsenic, etc.) or P-type dopants (e.g. Boron, Indium, etc.). In some exemplary implementations, a laser 407 may be used to crystallize the layer 406. In exemplary implementations, the laser 407 to crystallize layer 406 may be a solid state laser with a wavelength between about 266 nm and about 2 μm. In other implementations, a heat lamp or strip heater may be used to crystallize the layer 406. The laser or heat lamp/strip heater etc. may be used through the substrate as shown in FIG. 4 or in other implementations may be incident on the substrate from the top. In some implementations, it may be desirable to leave layer 406 partially or fully amorphous (non-crystallized) to take advantage of the better light absorption properties of amorphous silicon. Here, aspects of the innovations herein may relate to the creation of a layer of crystallized silicon on a substrate/glass using a 2-step process. In exemplary implementations, this silicon layer can be between about 0.03 μm and about 25 μm thick. This thickness is substantially less than the 150 μm thick silicon wafers that are used to make the dominant solar cells in the marketplace. In exemplary implementations, the layer 403 (1^{st} silicon-containing layer) can be about 20 nm to about 200 nm thick and layer 406 (2^{nd} silicon containing layer) can be about 50 nm to about 25 μm thick.

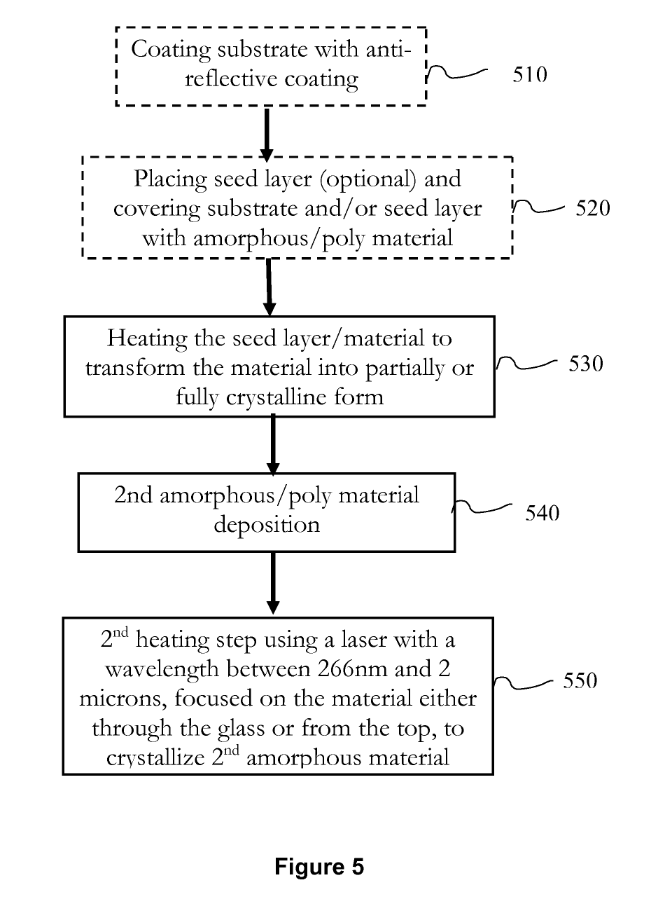

FIG. 5 is flow chart illustrating an exemplary implementation consistent with one or more aspects of the innovations herein. The flow chart shows an optional anti-reflective coating deposition 510, followed by placing the optional seed layer on the substrate and coating with the amorphous silicon-containing material 520. This may be followed by heating the material and the seed layer 530, for example, by a laser to partially or fully crystallize the amorphous material. A second amorphous layer may then be deposited 540, followed by a second heating step 550 to crystallize the material. In both the heating steps, for example, the laser beam or lamp source, may be focused from the top, through the substrate, or through both. The details of flow diagram for one specific sequence of the steps, shown in FIG. 5, consistent with the innovations herein are listed below.

Step 510: (Optional) Deposition of anti-reflective coating (preferably SiN/SiO2). The anti-reflective coating in exemplary implementations is either a layer of SiN (silicon nitride) or SiO₂ or a combination of the 2 layers. The thickness range for SiN can be about 50 nm to about 250 nm preferably about 75 nm. In certain implementations, a SiN thickness of about 150 nm may also be utilized. The thickness range for SiO2 can be 0 (no SiO2) to about 200 nm preferably about 20 nm.

Step 520: (Optional) Bonding of seed layer to the anti-reflective coating. FIG. 2 shows this step. In certain implementations, this step may be done after the amorphous/poly silicon-containing layer deposition or in some implementations skipped entirely. The seed layer thickness can be about 50 nm to about 100 μm, preferably about 350 nm.

Deposition of amorphous/poly silicon (also shown as part of step 520 in FIG. 5). FIG. 3 shows this step after the seed layer bonding. An alternative approach of doing the amorphous/poly silicon-containing layer deposition is shown in FIG. 2. The silicon-containing layer thickness can be about 20 nm to about 1000 nm or about 45 nm in some specific implementations.

Step 530: First crystallization. Following are some parameters of illustrative implementations using a laser. Here, for example, the laser wavelength may be between about 266 nm and about 2 μm, and/or in some implementations, in the green region such as 532 nm or 515 nm. In addition, the crystallization may be done with a nitrogen or argon gas flowing around the film to reduce the oxygen content of the film after crystallization. Further, the flow of nitrogen or argon gas may also be accomplished by enclosing the substrate in a chamber and filling the chamber with nitrogen or argon gas.

Step 540: Deposition of second amorphous/poly silicon-containing layer. Here, it should be noted that, prior to deposition of the second amorphous layer, an optional soft etch may be performed. The soft etch may be used to remove any native oxide on top of the first amorphous silicon layer. In addition, the soft etch may be tailored to roughen the surface of the first amorphous layer to improve the adhesion of the second amorphous layer. Turning to exemplary implementations of providing the second layer, the second amorphous/poly silicon-containing layers may be deposited by various techniques, such as PECVD (plasma enhanced chemical vapor deposition) or HWCVD (hot-wire CVD) using a silicon-source gas such as silane (SiH₄). Further, such second amorphous/poly silicon layer can be between about 50 nm and about 25 μm, or about 4 μm in thickness for certain implementations, as shown in FIG. 4. In some implementations, there may be a cover layer such as silicon nitride or silicon dioxide on top of the second amorphous layer. An exemplary implementation of the cover layer, would use silicon nitride and this cover layer may be introduced by exposing the second amorphous layer to a plasma containing nitrogen such as nitrogen or ammonia (NH3) gas.

Step 550: Laser crystallization of second amorphous/poly silicon-containing layer. Here, for example, the laser wavelength may be between about 266 nm and about 2 μm, and may be in the infra-red region such as 880 nm or 1.06 μm. Further, the laser may be focused on the silicon containing film from the top and/or through the substrate. In addition, the crystallization may be done with a nitrogen or argon gas flowing around the film to reduce the oxygen content of the film after crystallization. The flow of nitrogen or argon gas may also be accomplished by enclosing the substrate in a chamber and filling the chamber with nitrogen or argon gas.

In summary, FIG. 5 shows the flow chart of an exemplary implementation of the steps needed to achieve a partially or fully crystallized silicon-containing film on a substrate such as glass, metal or plastic. The substrate may, for example, be glass such as boro-silicate, aluminosilicate or soda-lime glass. The substrate may also be metal foil such as aluminum or steel or NiW. Such a silicon-containing crystallized film is very useful for several applications such as solar cells, photodetectors as well as thin-film transistors and flat panel displays.

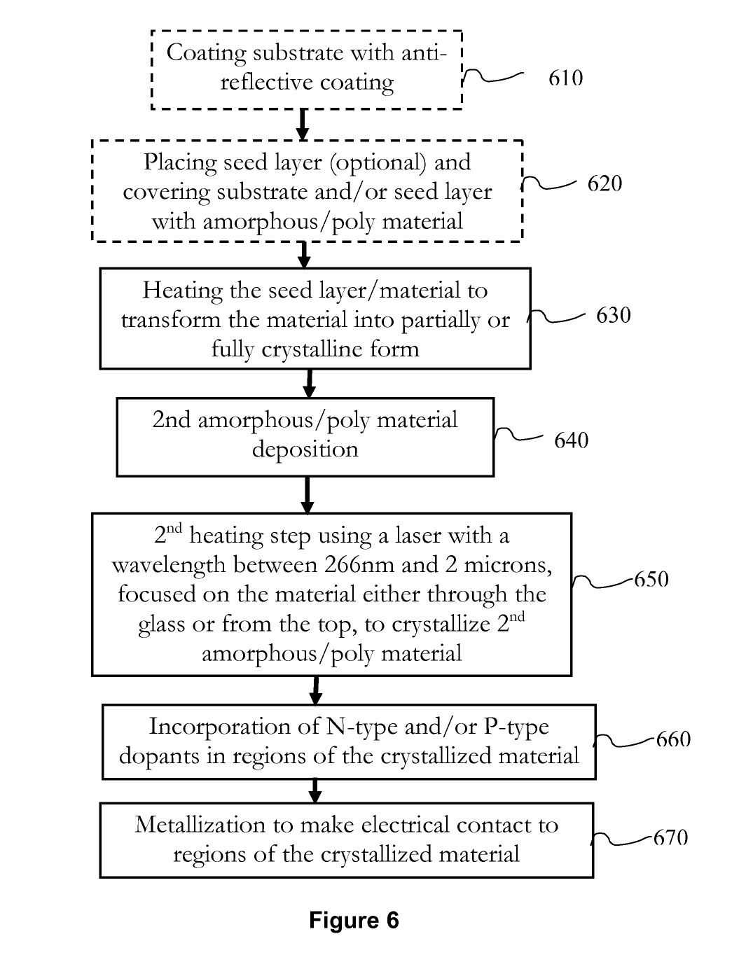

FIG. 6 shows an exemplary implementation of the innovations contained herein including the further steps that are needed to make electrical contact to the crystallized silicon-containing film. Here, steps 610 through 650 are similar to the steps 510 through 550 described above in FIG. 5. The additional steps are described in detail below.

Step 660: Incorporation of N and P dopants. According to certain implementations, the N and P dopants may be done before Step 650 (crystallization of the second amorphous/poly silicon-containing layer). In some implementations, one of the dopants may be skipped entirely, such as the P-type dopant (Boron). Further, dopant incorporation in exemplary implementations may be done using a dopant paste and a laser shining on the regions where the dopants are to be incorporated. Other methods of dopant incorporation may be used in some implementations, such as depositing a doped silicon layer. Further exemplary methods are possible. For example, where the N-type dopant such as phosphorous is incorporated using a liquid source such as phosphoric acid (H3PO4).

Step 670: Metallization. As shown in FIG. 6, in certain exemplary implementations, a dielectric layer or dielectric layers such as silicon dioxide or SiN may be added. The SiN thickness can be between about 20 nm and about 1 μm, or in certain implementations about 500 nm (0.5 μm). In other exemplary implementations the layer could be S102 preferably about 1 μm thick. Such SiO2 layer may be deposited on top of SiN layer which may be used to protect the crystallized silicon-containing layer. The SiO2 layer may be deposited by various techniques, such as PECVD, using a liquid or paste such as spin-on-glass, etc. The metallization may be of various conductive and/or metal materials or compositions, such as Aluminum, Silver, etc. Aluminum is a particular good candidate when less expensive material is desired.

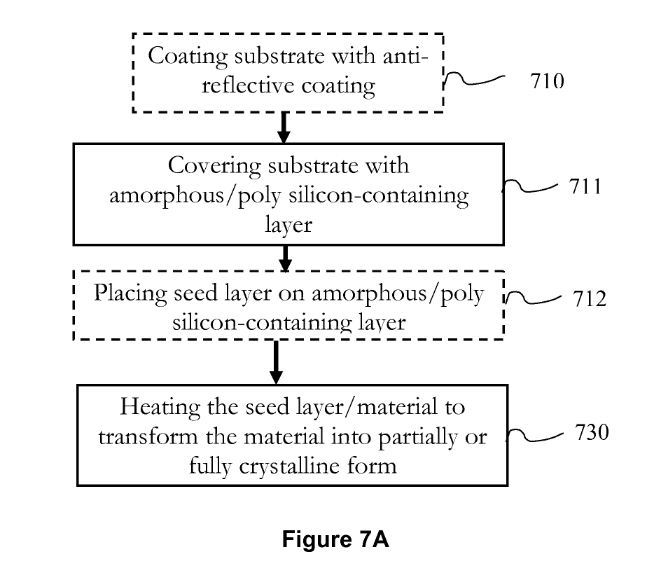

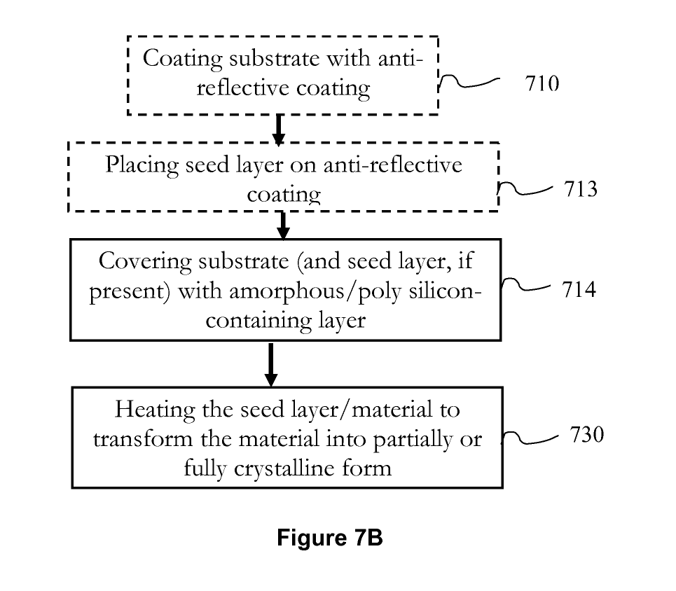

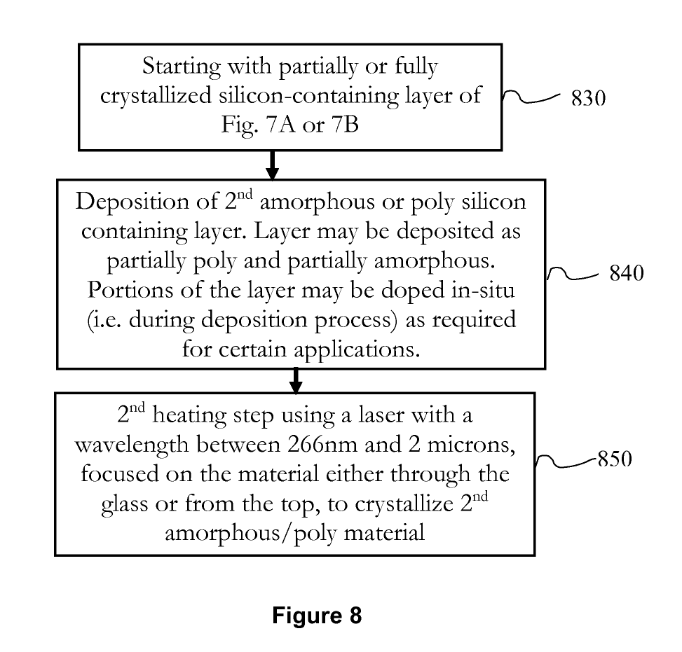

FIGS. 7A and 7B show detailed flow charts of alternative exemplary implementations of the steps leading up to the crystallization of the first amorphous/poly silicon containing layer, including an optional step of coating with an anti-reflective layer 710, covering the substrate with the amorphous/poly silicon 711, 714, and heating the seed layer/material 730. The optional seed layer may be placed on the substrate 712 after the first amorphous/poly silicon-containing layer deposition in FIG. 7A, whereas in the alternative implementation in FIG. 7B, the seed layer may be placed on the substrate 713 before the first amorphous/poly silicon-containing layer deposition.

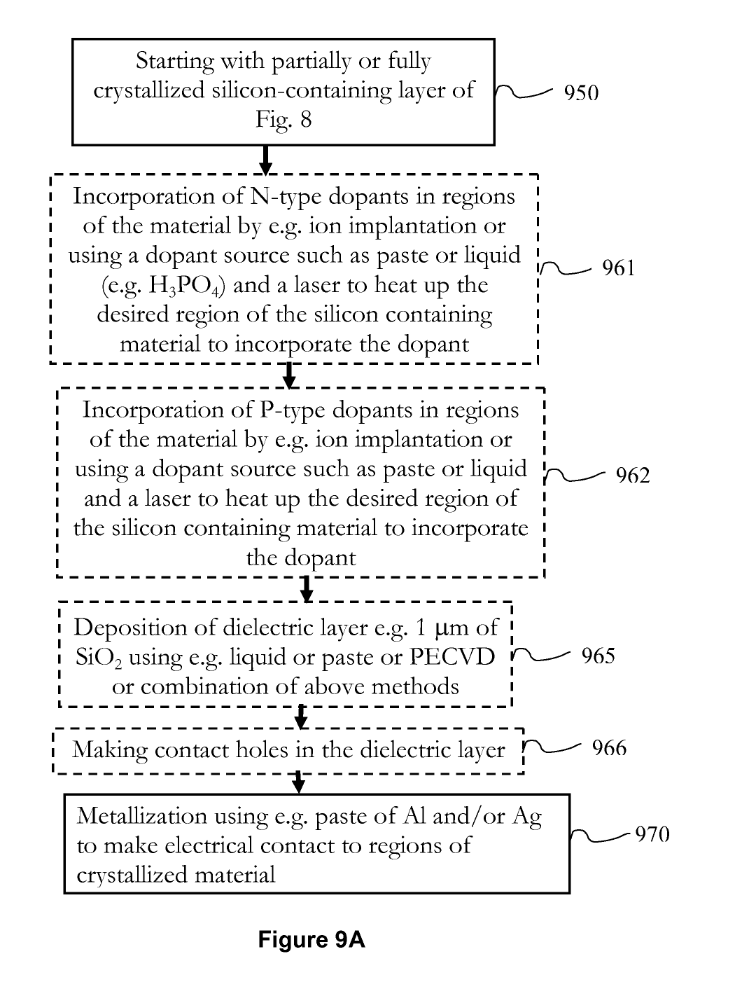

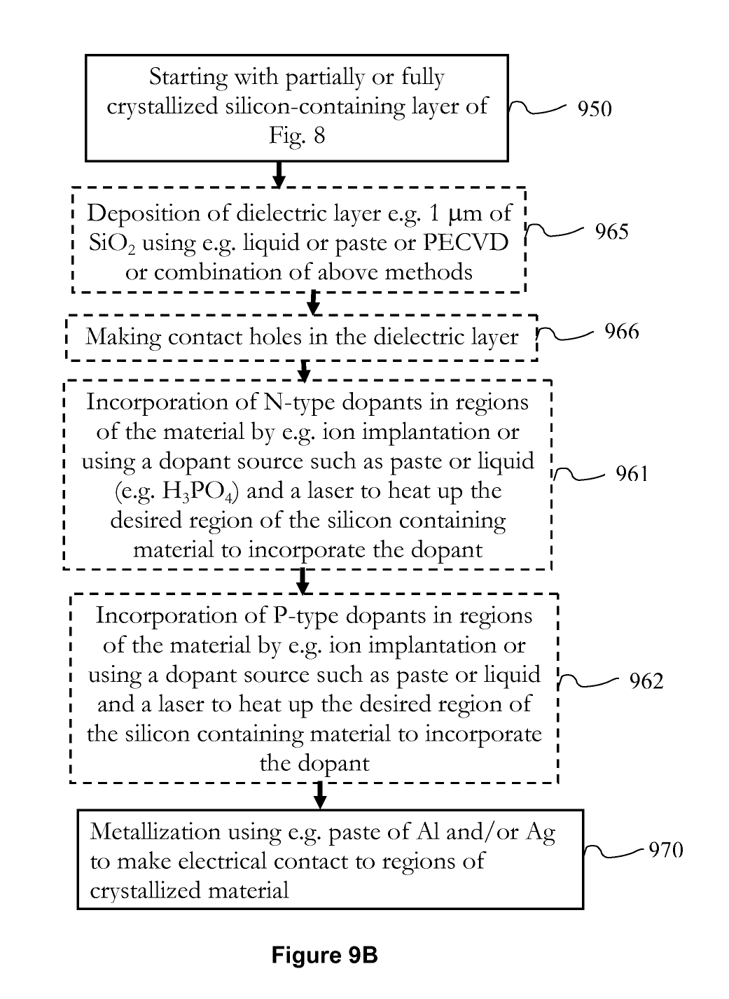

FIG. 8 shows a flow chart of details of an exemplary implementation of the steps starting from the partially or fully crystallized 1^{st} silicon-containing layer 830 and ending wall the 2^{nd} silicon-containing layer being partially or fully crystallized using a laser anneal in Step 850. As shown in Step 840, the silicon-containing layers may be deposited as partially polycrystalline and partially amorphous in certain applications. In certain exemplary implementations, the silicon-containing layers may be doped with N-type or P-type dopants, either in-situ or after the deposition.

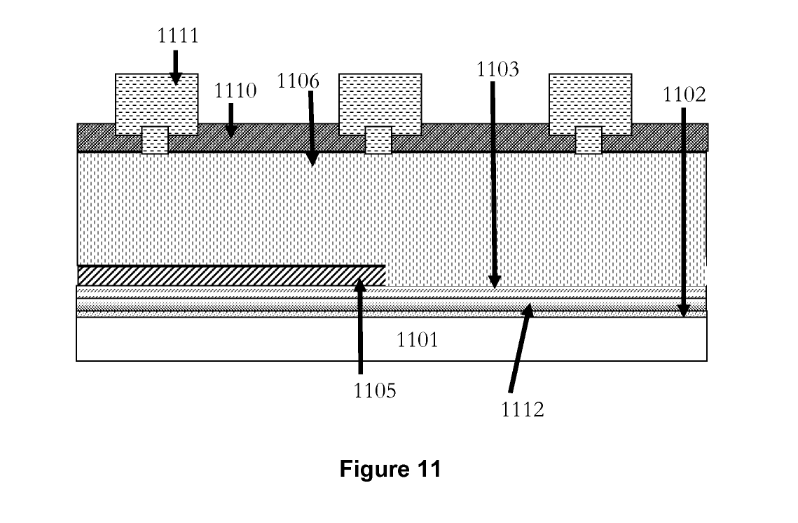

FIGS. 9A and 9B show details of exemplary implementations of the dopant incorporation and metallization of the silicon-containing layers (starting, at 950, with the layer of FIG. 8, for example), to make electrical connections to regions of the crystallized material. In FIG. 9A, for example, N-type dopants such as Phosphorous or Arsenic may be incorporated 961 in regions of the crystallized silicon-containing material. In exemplary implementations, this may be done using a dopant paste or a liquid source such as phosphoric acid (H₃PO₄). In step 962, the P-type dopants such as boron are incorporated in regions of the material. In some cases, only 1 type of dopant is needed, for example, because Aluminum metallization may act as the P-type dopant. This may also be the case for a front and backside contact solar cell shown in FIG. 11, that the dopants may be incorporated in-situ and therefore no additional dopant incorporation is needed. In FIG. 9A, a dielectric layer may also, optionally, be provided, such as via deposition. Here, for example, a dielectric layer such as one between about 0.2 μm and about 4 μm, or about 1 μm of SiO₂ may be deposited in step 965, followed by another optional step 966 of making holes in the dielectric layer, and then a step 970 of metallization.

In FIG. 9B, the step 965 and 966 are done prior to the dopant incorporation in the crystallized silicon film. It is to be noted that in some implementations, as described above for FIG. 9A, the dopant incorporation steps could be entirely skipped.

The doping shown in FIGS. 9A and 9B in step 961 and 962 may also be performed integral with the metallization. The initial steps (steps 310-370) of FIG. 3B are similar to those of FIG. 3 A. Furthermore, with regard to one exemplary implementation consistent with FIG. 9B, a dopant such as Antimony (Sb) may be incorporated into or onto a metallization paste (e.g. Silver paste), wherein both materials are then applied (e.g., screen printed onto) the surface (step 970). Next, a heating cycle is performed, such as with a lamp system or a laser. This process enables incorporation of the n-type dopant under the metal lines, wherein the metallization and N-type dopant are provided with a single application/process. Further, then, as Aluminum is a p-type dopant by itself, Aluminum lines could be screen printed to provide the complementary process for providing the anode along with the contact above it. Here, with an associated heating step, Aluminum contact lines would be provided and the Silicon under the Aluminum lines would get doped with the Al, wherein p-type regions are then created.

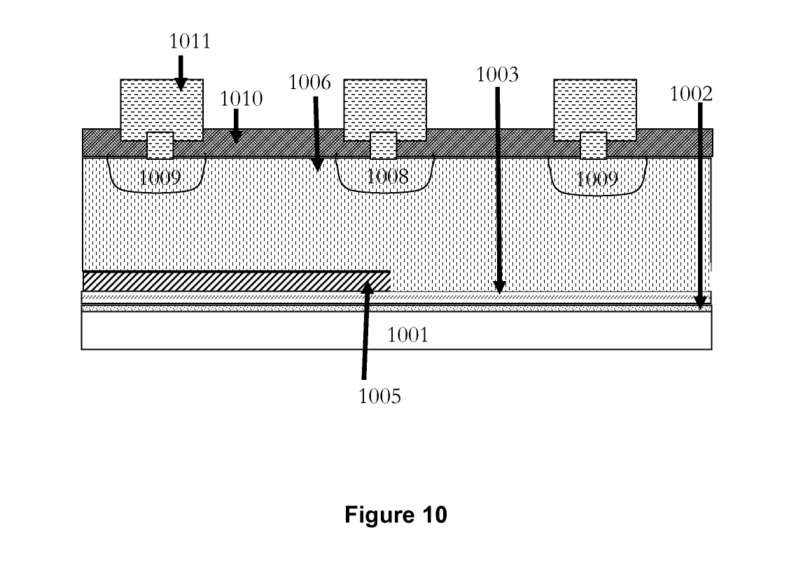

FIG. 10 illustrates an exemplary backside contact solar cell that can be manufactured consistent with aspects of the innovations herein. FIG. 10 shows an exemplary implementation where N and P type dopants are introduced in region 1008 and region 1009 inside the crystallized silicon layer. The dopant incorporation may be done before or after the crystallization of layer 1006 as desired. Dielectric layers 1010 and metallization layer 1011 may be used to achieve electrical contact to the solar cell. In some implementations, the dielectric layer 1010 may be skipped to reduce the process cost and complexity.

Some of the disclosure herein uses the terms “amorphous layers” or “amorphous silicon”, such as when describing crystallization of such layers using a silicon seed layer. However, the innovations herein are not limited to just amorphous layer(s), i.e., such layer could be poly crystalline or multi-crystalline. In addition, the amorphous/poly layer could contain substantial or even majority quantities of other materials including but not limited to Germanium (Ge), Carbon (C), Fluorine (F) etc. According to other implementations, the amorphous/poly material may be or include an amorphous/poly silicon layer that includes some Ge (to form SiGe) or C (to form SiC). The amorphous/poly material may be a silicon material that contains elements such as F (Fluorine), D (Deuterium), Hydrogen (H), Chlorine (Cl) etc., which may be useful in passivating the traps, grain boundaries, etc. in the crystallized silicon-containing film. The amorphous/poly material may also, in some implementations, include dopants such as B (Boron), Phorphorous (P), Arsenic (As) etc. incorporated in the film. In further implementations, the substrate or support layer (e.g., glass, etc.) can be replaced by other substrates such as plastics and/or metals. Overall, aspects of such innovations may lead to uniform grains, high carrier lifetime(s), and/or improved diffusion length(s) and mobilities.

FIG. 11 illustrates a front and backside contact solar cell that may be manufactured consistent with aspects of the innovations herein. In FIG. 11, an additional front-side (near substrate 1) contact 1112 is added. According to some exemplary implementations, this contact 1112 may be a transparent conductive layer such as ITO (Indium-Tin-Oxide). In other implementations, the front side contact may be lines of metal such as Aluminum (Al) or Silver (Ag). In further implementations, e.g. with both front and backside contacts, doped silicon layers may be used on the front and back sides of the solar cell.

As such, consistent with the innovations herein (for example, films of reduced thickness, which: (i) may be doped without the need for higher furnace temperatures e.g. via laser irradiation; and/or (ii) are characterized by smaller volumes that do not require higher furnace temperatures to passivate all of the traps throughout a e.g. 150-200 micron silicon wafer, etc.), all furnace steps associated with solar cell device fabrication may be performed at less than about 600° C., or at less than about 500° C. Moreover, in accordance with innovative processes set forth elsewhere herein, use of such thin silicon layers (e.g., about 0.5 μm to about 30 etc.) on base substrates without any furnace process above 500-600° C., further allows realization of very low material costs as well as use of low temperature substrates such as glass, plastic, etc., and hence lower manufacturing costs of the solar cells.

Backside Only Contacts Embodiments

Systems, methods, devices, and products by processes associated with thin-film solar cells having contacts on the backside, only, are also disclosed. Consistent with aspects of the present innovations, such implementations may relate to thin film devices comprising a substrate and a layer of silicon or silicon-containing material positioned on a first side of the substrate, wherein the layer comprises one or more n-doped region(s) and one or more p-doped region(s). Moreover, the innovations herein may include n-doped region(s) and the p-doped region(s) formed on the backside surface of the layer to create an electrical structure characterized by a P-type anode and an N-type cathode forming junction(s) positioned along the backside surface of the layer. Other exemplary implementations may further comprise one or more first contacts placed on the layer above, and electrically connected to, the n-doped region(s), as well as one or more second contacts place on the layer above, and electrically connected to, the p-doped region(s).

With regard to exemplary solar cell (or device) implementations, innovative cell architectures for thin-film solar cells are provided. Again, these architectures have both contacts (positive and negative or P-type and N-type) on the backside of the solar cell. Further, while a type of backside-only contact architecture has been used in some full-thickness crystalline silicon solar cells, the present innovations relate to devices consistent with thin film solar cells using, e.g., amorphous/poly silicon, as set forth herein.

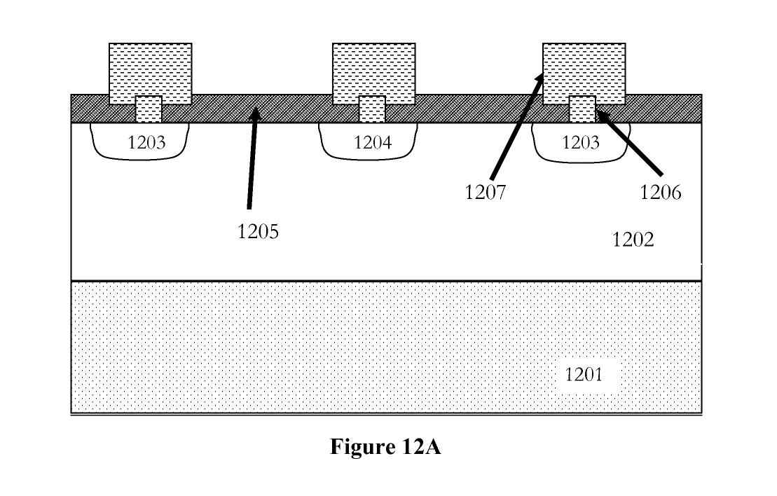

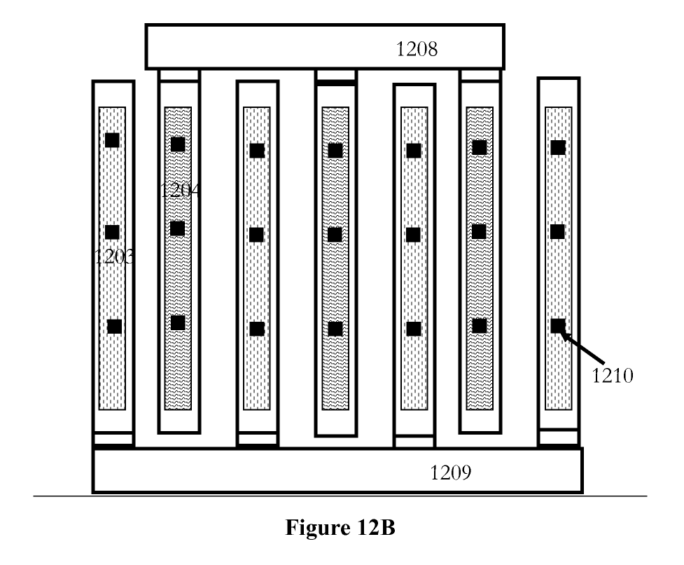

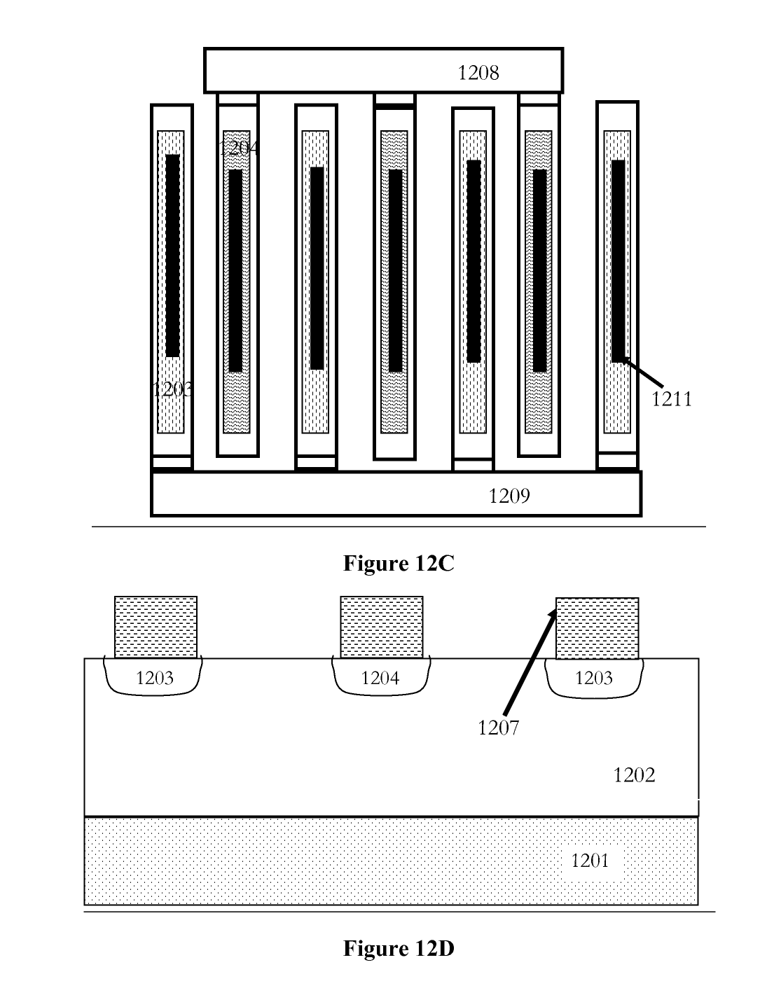

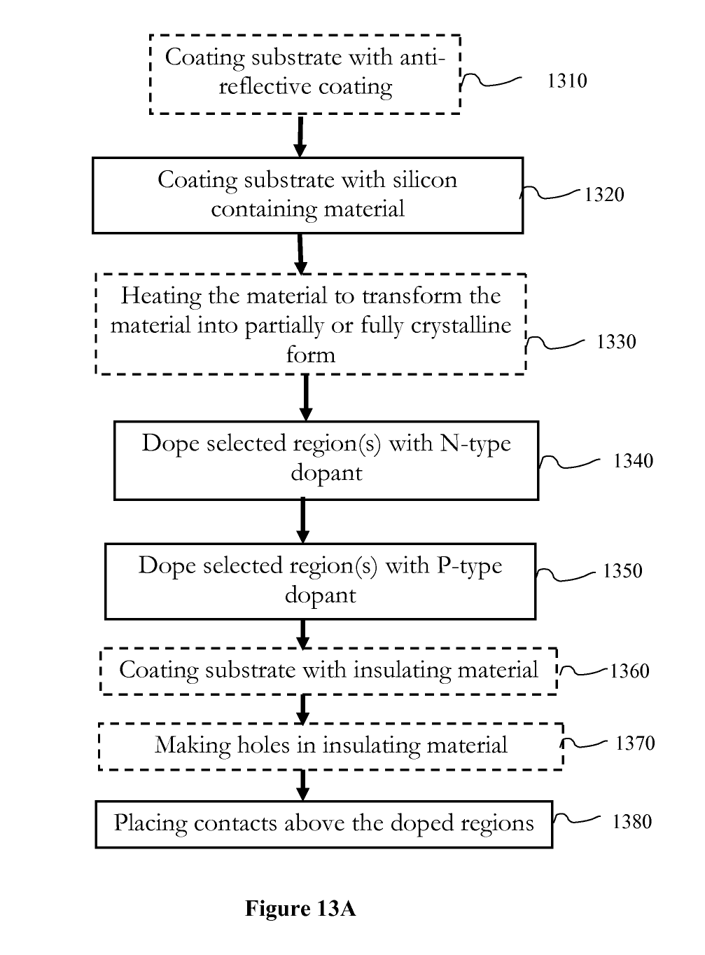

FIGS. 12A-12C illustrate several views of exemplary thin-film solar cell structures or devices, consistent with aspects related to the innovations herein. Referring to FIG. 12A, a cross-sectional view of an exemplary implementation of a solar cell structure is provided. Here, a substrate 1201, such as a glass sheet, is positioned on the front side of the structure, where e.g. sunlight will initially enter the solar cell. According to some implementations, a silicon or silicon-containing layer 1202 is positioned against the substrate 1201, on a side away from the entering sunlight. In one exemplary implementation, a thin film silicon layer may be deposited as an amorphous film and then crystallized either using a laser or other anneal, as set forth in more detail below. However, in other implementations the innovations herein, films may simply be deposited in amorphous or poly/multi/nano crystalline form, without further processing such as laser anneal prior to doping/contact formation. For purpose of illustration, N+ regions 1203 may first be defined and dopants such as arsenic or phosphorous are incorporated into these regions. In one approach, these atoms could be implanted into the silicon to form the N+ region(s) 1203. Other approaches may include doping via solid state diffusion from dopant sources or diffusion from gas sources including diffusion activated via laser irradiation. In this illustrative example, P+ regions 1204 may then be defined, wherein dopants such as boron and/or BF2 can be incorporated into these regions. The order of defining and doping the N+ and P+ regions is not critical and can be reversed depending on differing implementations of the present inventions. An insulating layer 1205 may then deposited or grown on the silicon layer. Further, in some implementations, this insulating layer could be comprised of multiple materials and layers. For example, in some implementations, a thin layer of oxide may be grown by plasma or other means and then a nitride layer may be deposited by a suitable means such as PECVD (plasma enhanced chemical vapor deposition). Finally, contact holes or slots 2106 are cut into the insulating layer 1205 and contacts 1207 may be deposited and patterned to make connections to the solar cell.

Accordingly, consistent with the innovations herein, the n-doped and p-doped regions may be disposed laterally and all the electrical contacts are at the backside of the solar cell. Beneficial aspects of such innovations may include a simplified contacting scheme, since a single contacting layer such as a metal layer can be used to connect both the n-doped and p-doped regions. Further, innovations are achieved via the ease of electrically coupling the individual areas within a solar panel, without the difficulty of fabricating contacts to the front-side of the solar cells. Moreover, the innovations recited herein provide devices, methods, architectures and products-by-processes that are low cost without the efficiency losses found in existing systems and techniques.

FIG. 12B illustrates a top view layout of an exemplary thin-film solar cell structure or device, consistent with aspects related to the innovations herein. FIG. 12B depicts one exemplary implementation of the present innovations, wherein the doped regions 1204 are shown connected to upper contacts structure a discrete points 1210, such as via holes that may be etched or otherwise cut through the insulating layer. Electrically conductive regions 1209, such as metal lines and/or plates are connected to the P+ and N+ regions. Here, FIG. 12B shows a parallel connection 1209 of all the metal lines going to the N+ (cathode) regions 1203 as well as another parallel connection 1208 of all the metal lines going to the P+ (anode) regions 1204. In should be noted, however, that in other implementations of the innovations herein, one or more combination(s) of series and parallel connections of the metal lines can be used to obtain the desired voltage and current from the solar cell. Additionally, the N+ regions 1203 and P+ regions 1204 are shown as alternating in this exemplary implementation. However, in other implementations, the N+ and P+ layers may be non-alternating. Moreover, in still other implementations, various further structures and arrangements may be used, such as two N+ regions with a P+ring-shaped region surrounding them, to provide the desired currents/voltages. Again, in this example, point contacts 1210 are shown for both the N+ and P+ regions.

FIG. 12C illustrates another top view layout of a further exemplary thin-film solar cell structure or device, consistent with aspects related to the innovations herein. The structures, doping and contacts of FIG. 12C are generally similar to those of FIG. 12B except that FIG. 12C illustrates an alternate backside contact solar cell implementation having “slot” contacts 1211 instead of the point (square or round) contacts 1210 as shown in FIG. 12B.

FIG. 12D illustrates another exemplary thin-film solar cell structure or device, consistent with aspects related to the innovations herein. Referring to FIG. 12D, an alternative backside contact solar cell without an insulating layer 1205 (FIG. 12A) is shown. While solar cells and devices with insulating layer(s) provide higher efficiencies, implementations consistent with FIG. 12D (without the insulating layer) are less costly to manufacture due to less complexity in the fabrication process and overall structural simplicity. In exemplary implementations consistent with FIG. 12D, contacts 1205 may be an electrically conductive layer, such as a metallization layer (singular) or layers (plural), which may be a metal such as silver (Ag) or Aluminum (Al), or even other metals, such as Nickel (Ni), Ti (Titanium), Cobalt (Co), and/or Palladium (Pd). In short, the contacts or metallization may be more than a single layer and/or more than a single metal. Here, for example, an initial layer of Nickel may be used to achieve good contact resistance, followed by Aluminum lines providing appropriate thickness for the metallization layer. Preferred embodiment is to screen print the metallization layer. However, other methods such as PVD (physical vapor deposition), CVD (chemical vapor deposition), evaporation can be used.

According to some implementations of the innovations herein, a layer such as an anti-reflective layer of SiN, SIO2 or SiON may be provided between the substrate 1201 and the amorphous/poly layer 1202. In exemplary implementations, the amorphous/poly layer 1202 may be amorphous silicon. Further, in some implementations, the amorphous/poly layer or amorphous silicon may have reduced hydrogen content. Here, for example, the reduced hydrogen content may be achieved by adjustment of the deposition method, such as using different gases or gas ratios in the deposition chamber and/or by adding a post-deposition anneal to drive out the hydrogen. A laser may then be applied and scanned across the substrate, e.g., to transform the silicon into crystalline or partially crystalline form. It should be noted that the inventions herein are not limited to particular laser wavelengths or optics needed to create certain spot sizes and shapes, such as a line source or other shapes. Instead, the innovations herein encompass all such variations as long as the energy density crystallizes or partially crystallizes the amorphous/poly layer.

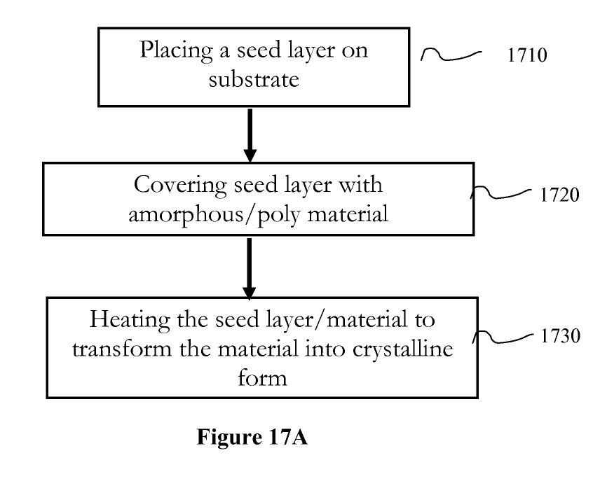

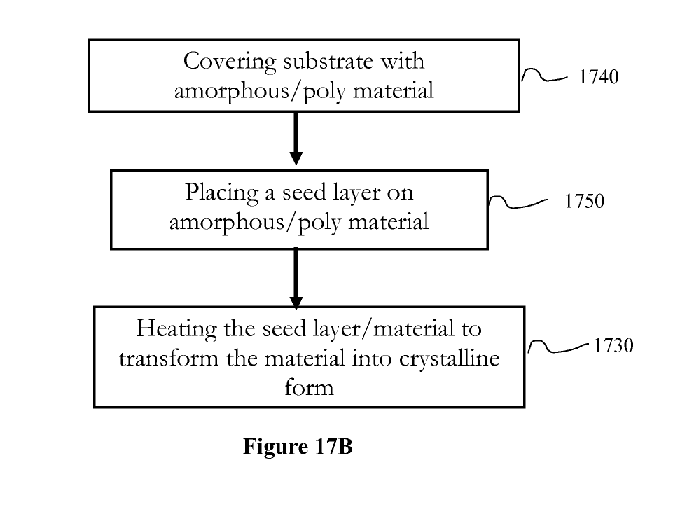

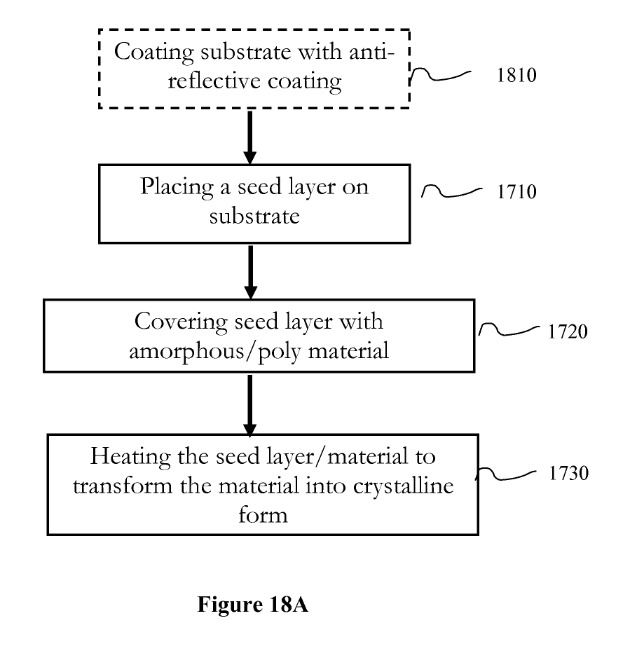

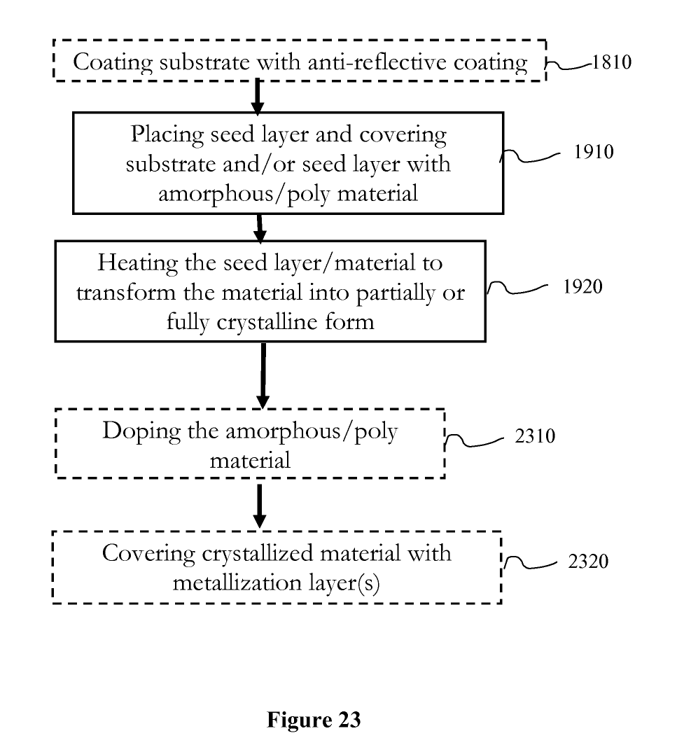

The present disclosure is initially directed to aspects associated with backside only contact thin film solar cells. Various other steps, products and processes consistent with the innovations set forth herein are also disclosed, as described in more detail beginning with FIG. 17A. These implementations, for example, may include bonding a seed layer of crystalline silicon which can be a wafer, or a part of a silicon wafer, on glass. Further, these implementations may also have another layer, for instance and anti-reflective coating, deposited before bonding the seed layer. The seed layer may also be affixed to the glass sheet by methods other than silicon bonding, such as with a glue layer. Alternative implementations include placing the silicon layer on the substrate using mechanical means such as mechanical pressure, vacuum etc. Detail of these, and other, exemplary implementations are set forth in connection with FIGS. 17A-22. Some applications consistent with the innovations herein include solar cells (FIGS. 23-25). However, the innovations herein are not limited to just such exemplary applications, but can be used for other applications as well.

Some of the disclosure herein uses the terms “amorphous layers” or “amorphous silicon”, such as when describing crystallization of such layers using a silicon seed layer. However, the innovations herein are not limited to just amorphous layer(s), i.e., such layer could be poly crystalline or multi-crystalline. In addition, the amorphous/poly layer could contain substantial or even majority quantities of other materials including but not limited to Germanium (Ge), Carbon (C), Fluorine (F) etc. According to other implementations, the amorphous/poly material may be or include an amorphous/poly silicon layer that includes some Ge (to form SiGe) or C (to form SiC). The amorphous/poly material may be a silicon material that contains elements such as F (Fluorine), D (Deuterium), Hydrogen (H), Chlorine (Cl) etc., which may be useful in passivating the traps, grain boundaries, etc. in the crystallized silicon-containing film. The amorphous/poly material may also, in some implementations, include dopants such as B (Boron), Phorphorous (P), Arsenic (As) etc. incorporated in the film. In further implementations, the substrate or support layer (e.g., glass, etc.) can be replaced by other substrates such as plastics and/or metals. Overall, aspects of such innovations may lead to uniform grains, high carrier lifetime(s), and/or improved diffusion length(s) and mobilities.

Turning back to the laser anneal aspects, the amorphous/poly layer 1203 may then be crystallized via heat application such as laser irradiation. In some exemplary implementations, such irradiation may be performed by a solid state laser with a wavelength between about 266 nm and about 2 μm. In certain exemplary implementations, the laser may be a solid state laser with a wavelength of about 515 nm or about 532 nm. The laser may be applied from the top of the substrate. However, in other implementations described elsewhere herein, the laser can also be applied from the bottom (through the substrate 1201), i.e., when the substrate is mostly transparent to the laser wavelength used/selected. The choice of the laser being used from the top or through substrate may depend on the type of substrate being used as well as the types of materials used in and thicknesses of the anti-reflective coating and the amorphous/poly material(s).

As discussed herein, aspects of the innovations herein may include coating layers either on the outside of the substrate/glass layer, or in between the glass and the silicon layer, or in both places. Examples of such coating layers may include additional anti-reflective coating on the outside (light facing) side of the glass layer and/or a SiN or SiON or SiO2 layer or combination of these between the glass and silicon layer. In addition, still further aspects of the innovations herein may include other methods of crystallization, such as heat sources such as carbon strips or lamps which can be used to supply the heat needed for crystallization. Innovations herein are also applicable to other semiconductor materials such as SiGe (silicon-germanium) or SiC (silicon-carbide).

According to exemplary implementations of the innovations herein, a seed layer may be used and the seed layer may even be a silicon wafer or piece thereof. Further, consistent with some implementations, such piece of silicon wafer may applied with the desired thickness or it may be simultaneously or sequentially reduced in thickness by a suitable method such as cleaving, etching, polishing, etc., e.g., in one exemplary implementation, to a thickness of about 0.05 μm to about 100 μm. Here, such exemplary part of silicon wafer could be piece reduced in thickness by cleaving or thinning the wafer after bonding to leave only a thin layer on the glass. Additional details of such thin film fabrication processing including substrates with seed layers, and related processing, may be found in U.S. patent application Ser. No. 12/842,996, filed Jul. 23, 2010, published as U.S. patent application publication Ser. No. ______, now U.S. patent Ser. No. ______, and U.S. patent application Ser. No. 12/845,691, filed Jul. 28, 2010, published as U.S. patent application publication Ser. No. ______, now U.S. patent Ser. No. ______ which are incorporated herein by reference in entirety. Further descriptions of the use of lasers to crystallize the amorphous/poly layer are set forth in more detail further below.

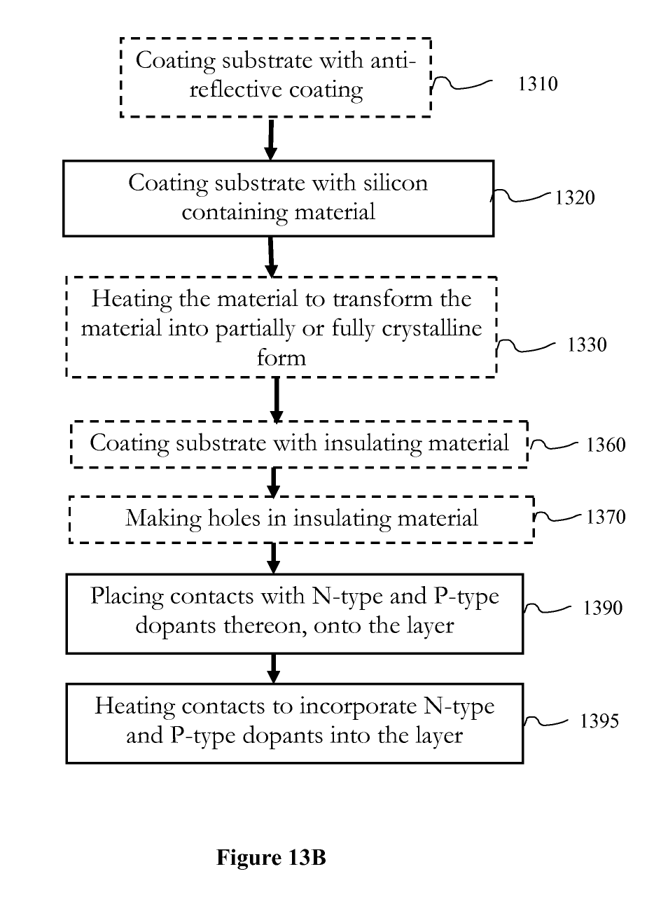

FIGS. 13A and 13B illustrate exemplary methods related to fabrication of thin-film substrates, consistent with aspects related to the innovations herein. Referring to FIG. 13 A, an initial step of coating the substrate with amorphous/poly material may be performed (step 1320). Here, a silicon layer or silicon containing layer that does not require further processing prior to doping may be provided. Alternately, for example, a seed layer may also be applied first with the amorphous/poly material on top, or the amorphous/poly material may be applied first, as explained elsewhere herein. Next, an optional step of heating the amorphous/poly material and seed layer (step 1330) may then be performed, until the material is transformed into partially or fully crystalline form. Here, for example, this heating step may comprise any of the heating and/or laser application techniques set forth herein.

Next, in some exemplary implementations, dedicated doping steps (steps 1340 and 1350) may be performed. Here, the N+ and P+ regions may be doped in several ways; further, the N-type doping may be done first or the P-type doping may be done first. In one exemplary implementation, the silicon layer may be coated with dopant paste followed by a laser application on the region where the dopant is to be incorporated (step 1340). For example, this could be a paste containing an N-type dopant such as Arsenic, Phosphorous or Antimony. Following the incorporation of the first dopant, the paste is cleaned off and a second paste, e.g., containing a P-type dopant such as Boron may, be coated on the silicon over the regions where the anode structures are desired. Next, a second doping step is performed to dope the selected regions with p-type material (step 1350). Here, for example, another heating step may be performed (not shown), via a lamp or laser, to irradiate the regions where the p-type dopant is to be incorporated. Once completed, the associated paste is cleaned off as well.

At this point, the silicon layer has both the N-type and P-type dopants incorporated. In implementations including an insulating layer, an insulating material may now be deposited (step 1360). Here, for example, the insulating layer may be SiO₂, or SiN or SiON. In an insulating layer is formed, then contact holes must be opened in the insulating layer (step 1370). In some implementations, laser ablation may be performed to open the contact holes. Other approaches like photolithography using masks or inkjet printing may also be used.

Contacts are then placed above the doped regions, step 1380. If an insulating layer has been deposited, the contacts are typically placed over the insulating layer once the contact holes are open. The contacts may be one or more electrically conductive materials or metals, as set forth below and elsewhere herein, and provided by means of known techniques, such as metallization process(es) suitable for placing metals on silicon substrates. Here, for example, exemplary metallization layers may be provided in several steps. In one exemplary implementation, Nickel (Ni) is deposited and then the substrate is heated to about 200° C. to about 500° C., or to about 300° C. Next, the unreacted Nickel, e.g., on top of the insulating layer, may be stripped away. The Nickel that is in the contact holes will form Nickel silicide which can create very low contact resistance. Al or Ag may then be screen-printed to create the metal lines. Then, one or more anneal processes may then be performed at temperature ranges between about 300° C. and about 650° C. or between about 400° C. and about 450° C., to make the metallization stable. In one exemplary implementation, the anneal may be comprised of 2 steps, one performed at about 200° C. and then a higher temperature anneal at about 450° C. Finally, an optional insulating layer such as SiO2, SiN or SiON or EVA (Ethyl vinyl acetate) may be applied to cover the metallization layer.

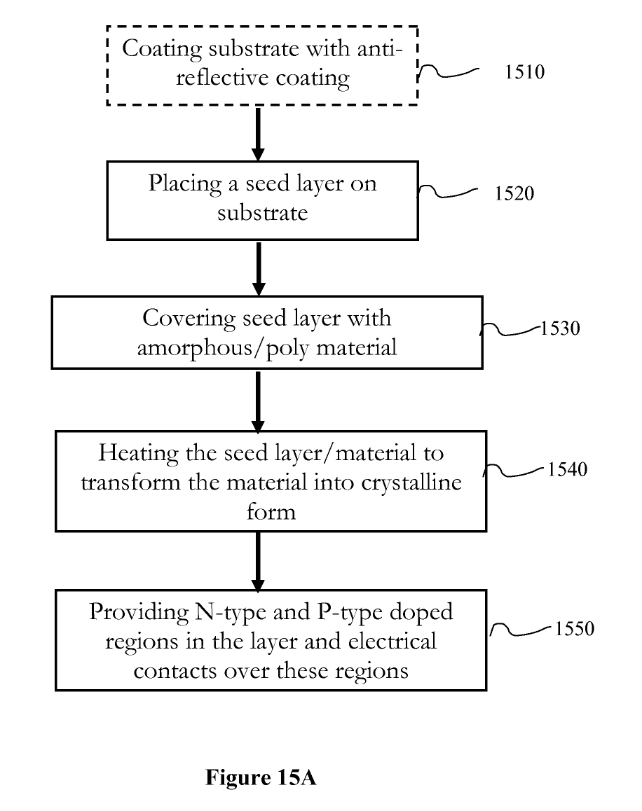

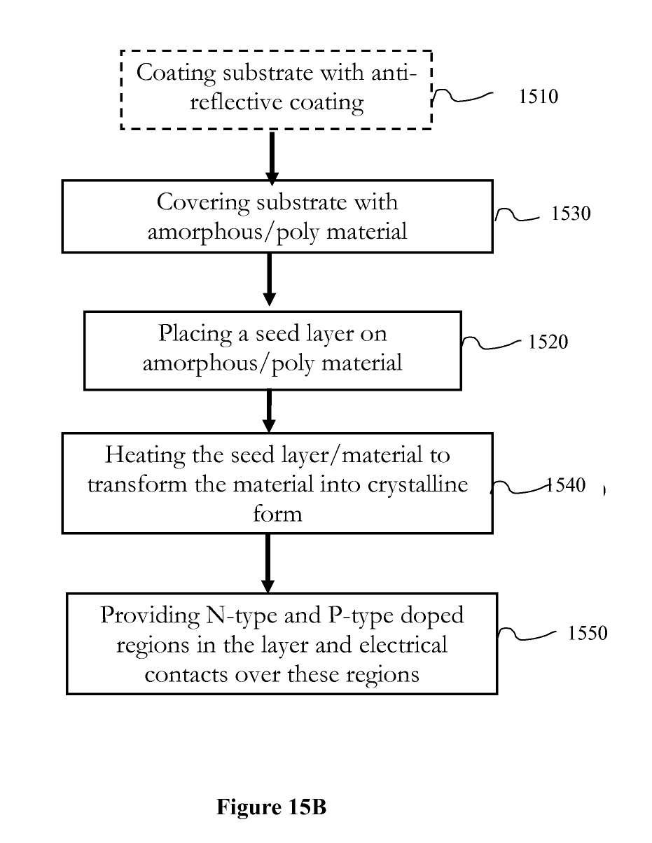

According to the innovations of FIG. 13B, the doping may also be performed integral with the metallization. The initial steps (steps 1310-1370) of FIG. 13B are similar to those of FIG. 13 A. Furthermore, with regard to one exemplary implementation consistent with FIG. 13B, a dopant such as Antimony (Sb) may be incorporated into or onto a metallization paste (e.g. Silver paste), wherein both materials are then applied (e.g., screen printed onto) the surface (step 1390). Next, a heating cycle is performed (step 1395), such as with a lamp system or a laser. This process enables incorporation of the n-type dopant under the metal lines, wherein the metallization and N-type dopant are provided with a single application/process. Further, then, as Aluminum is a p-type dopant by itself, Aluminum lines could be screen printed to provide the complementary process for providing the anode along with the contact above it. Here, with an associated heating step, Aluminum contact lines would be provided and the Silicon under the Aluminum lines would get doped with the Al, wherein p-type regions are then created. Lastly, as an optional process, an initial step of coating the substrate with an anti-reflective coating (step 1310) may be performed prior to the placement and heating of the silicon materials on the substrate, as set forth in more detail above in association with FIGS. 15A and 15B.

As such, consistent with the innovations herein (for example, films of reduced thickness, which: (i) may be doped without the need for higher furnace temperatures e.g. via laser irradiation; and/or (ii) are characterized by smaller volumes that do not require higher furnace temperatures to passivate all of the traps throughout a e.g. 150-200 micron silicon wafer, etc.), all furnace steps associated with solar cell device fabrication may be performed at less than about 600° C., or at less than about 500° C. Moreover, in accordance with innovative processes consistent with FIGS. 13A and 13B and/or as set forth elsewhere herein, use of such thin silicon layers (e.g., about 0.5 μm to about 30 μm, etc.) on base substrates without any furnace process above 500-600° C., further allows realization of very low material costs as well as use of low temperature substrates such as glass, plastic, etc., and hence lower manufacturing costs of the solar cells.

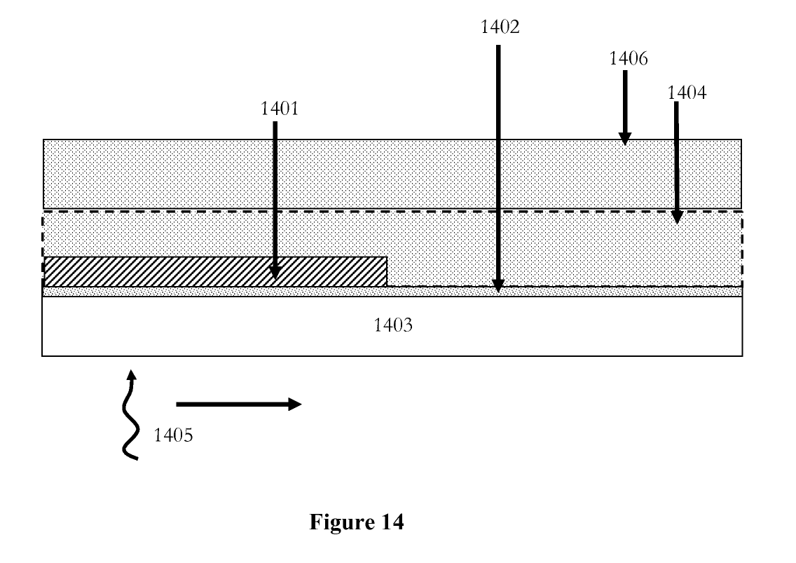

FIG. 14 illustrates a substrate having a seed layer above an amorphous/poly material layer, receiving laser irradiation to crystallize the amorphous/poly layer, consistent with aspects related to the innovations herein. It should be noted that, while use of crystallized silicon (as described here and elsewhere) yields further benefits for certain implementations, it is not necessary for all of the innovative solar cell architectures herein. In FIG. 14, a substrate 403 having a seed layer 1401 beneath a first amorphous/poly material layer 404 as well as a layer of second amorphous/poly material 406 on top of the first, and receiving laser irradiation from the bottom 405 to crystallize the amorphous/poly material, is shown. Referring to the exemplary implementation of FIG. 14, the substrate 1403 may be coated with an optional anti-reflective layer 1402 and an amorphous/poly layer 1404 such as a silicon layer or a silicon-containing layer. Further, the seed layer 1401 may already be bonded on the anti-reflective layer 1402 and crystallized with heat or laser. As further shown in FIG. 14, a second amorphous/poly layer 1406, such as a silicon or silicon containing layer, may be deposited on top of the first amorphous/poly layer 1404. The second amorphous/poly layer 1406 may be amorphous silicon similar to the first amorphous layer 1404. In some implementations, the second silicon containing layer 406 may be polysilicon or silicon-germanium (SiGe). In other words, the layer 1406 and layer 1404 may be the same composition or different compositions. In some exemplary implementations, a laser 1405 may be used to crystallize the layer 1406, in particular, via the sub-melt laser anneal processes herein. Further, in some implementations, it may be desirable to leave layer 1406 partially or fully amorphous (non-crystallized) to take advantage of the better light absorption properties of amorphous silicon. Here, aspects of the innovations herein may relate to the creation of a layer of crystallized silicon on a substrate/glass using a 2-step process. In exemplary implementations, this silicon layer can be between about 0.05 μm and about 25 μm thick. Moreover, such thicknesses are substantially less than the 150 μm thick silicon wafers that are used to make the dominant solar cells in the marketplace.

FIGS. 15A and 15B depict exemplary methods related to fabrication of thin-film substrates, consistent with aspects related to the innovations herein. Referring to FIG. 15A, an exemplary method of achieving a backside only contact thin film solar cells is illustrated. As shown in FIG. 15A, a silicon-containing seed layer may be placed on a substrate, such as glass (step 1520). This crystalline silicon-containing seed layer may be placed on top of the substrate, or it may be placed on top of another layer such as an anti-reflective coating, as explained in more detail above. Here, the seed layer may also be bonded to the substrate or other layer by means of electrostatic bonding. The seed layer may also be placed by mechanical means, such as vacuum. In other implementations, either hydrophilic or hydrophobic bonding may be used. In some implementations, bonding using a laser or other heat source may be used. In some exemplary implementations, the seed layer may be about 50 nm to about 100 micrometers, in other exemplary implementations about 200 nm to about 600 nm, and in still other exemplary implementation, about 350 or about 355 nm. Next, in step 1530, the seed layer may be covered with an amorphous/poly material, such as amorphous/poly silicon or another amorphous/poly silicon-based material. Other amorphous/poly silicon containing materials include SiGe (silicon-germanium) or SiC (silicon carbide) or SiGeC (silicon-germanium-carbide). In some implementations, the silicon containing amorphous/poly material may have intentional incorporation of deuterium or fluorine. In some exemplary implementations, the amorphous/poly material may be deposited via depositions processes such as CVD or PECVD (plasma enhanced chemical vapor deposition), via sputtering processes, or other known processes of depositing such layer(s). Here, for example, an amorphous/poly layer having a thickness of about 20 nm to about 1000 nm may be deposited over the seed layer. In further exemplary implementations, a layer of about 30 nm to about 60 nm may be deposited on the seed layer, and in still further exemplary implementations, a layer of about 45 nm may be deposited. Additionally, in step 1540, the seed layer and amorphous/poly material may be heated to transform these materials into crystalline form. Here, for example, these materials may be heated by conventional heating mechanisms used, such as strip heaters or lamps, and/or they may be heated via lasers to crystallize the material, such as via the sub-melt laser anneal processes set forth above or the laser crystallization processes set forth below. In some implementations using lamps, the lamps may be configured in the form of a line source focused on the material. In some exemplary implementations, a laser of wavelength between about 266 nm and about 2 micrometers may be applied to the materials to transform them into crystalline form. In other exemplary implementations, lasers of wavelengths from about 400 nm to about 700 nm may be used, lasers of green wavelength may be used, lasers of ultraviolet wavelength may be used, and/or in still further exemplary implementations, a laser having a wavelength of about 532 nm or about 515 nm may be used. Finally, a step of providing N-type and P-type doped regions in the layer as well as electrical contacts over these regions (step 1550) may then be performed, as set forth in more detail above. Here, the doped regions may be created first, with the contacts being provided afterwards via a separate process, or the dopants may be provided on/along with the contacts and infused into the layer via a subsequent heating process. Further, as an optional process, an initial step of coating the substrate with an anti-reflective coating (step 1510) may be performed prior to the placement and heating of the silicon materials on the substrate.

In general, the laser anneal processes herein may be optimized to grow the crystal vertically on top of the seed layer, and may also be applied to grow the crystal laterally on the side of the seed layer. According to exemplary implementations of the present innovations, the lasers used herein may utilize different settings such as power, pulse energy, scan speed, and spot size (e.g., on top of the seed layer, etc.), and/or different settings or even different lasers when being irradiated on the sides of the seed layers.

FIG. 15B illustrates an exemplary method of crystallizing silicon/silicon-based materials on a substrate, consistent with aspects of the innovations herein. FIG. 15B illustrates an alternate implementation of the innovations herein involving similar steps of FIG. 15A, although with the order of placing the amorphous/poly material and seed layer on the substrate reversed. In other words, in FIG. 15B, the substrate is first covered, in step 1530 with the amorphous/poly material. Then, in step 1520, a silicon-containing seed layer or material is placed on top of the amorphous/poly material. The processes and materials used, here, may be similar to those set forth in connection with FIG. 15A above. Then, once the amorphous/poly material and seed layer are in place, these materials are heated (step 1540) using techniques consistent with those set forth above in connection with FIG. 15A or elsewhere herein. In some implementations of the techniques shown in FIG. 15A or FIG. 15B, the laser source may be through the glass. In other implementations, the laser source may be directly incident on the material and seed from the top. Finally, a step of providing N-type and P-type doped regions in the layer as well as electrical contacts over these regions (step 1550) may then be performed, as set forth in more detail above. Here, the doped regions may be created first, with the contacts being provided afterwards via a separate process, or the dopants may be provided on/along with the contacts and infused into the layer via a subsequent heating process. Further, as an optional process, an initial step of coating the substrate with an anti-reflective coating (step 1510) may be performed prior to the placement and heating of the silicon materials on the substrate.

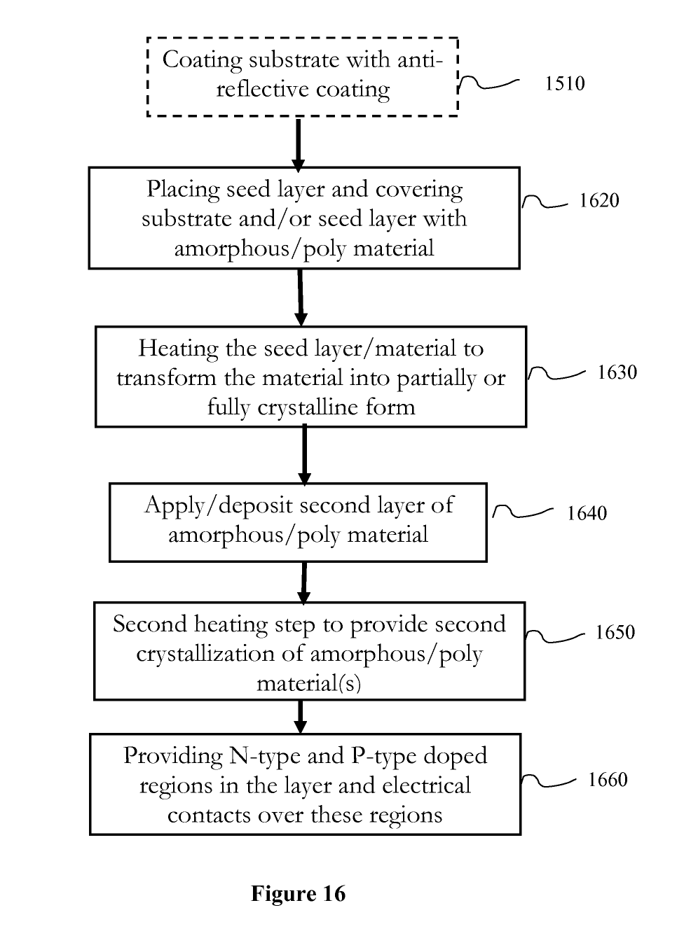

FIG. 16 illustrates another exemplary method related to fabrication of thin-film substrates, consistent with aspects related to the innovations herein. Referring to FIG. 16, an initial step of applying seed and amorphous/poly layers is performed (step 1620). Here, for example, the seed layer may be applied first with the amorphous/poly material on top, or the amorphous/poly material may be applied first as explained elsewhere herein. Next, a step of heating the seed layer and the amorphous/poly material (step 1630) is performed, until the material is transformed into partially or fully crystalline form. Here, for example, this heating step may comprise any of the heating and/or laser application techniques set forth herein. Another step of applying a second layer of amorphous/poly material is then performed (step 1640). Here, according to one or more exemplary implementations, a second amorphous/poly layer, such as a layer of amorphous silicon, having a thickness of about 50 nm to about 30 μm may be deposited. For example, a second amorphous/poly layer of between about 1 μm to about 8 μm may be deposited. According to some exemplary implementations, a second amorphous/poly layer of about 4 μm may be deposited. Further, prior to deposition of the second amorphous/poly layer, an optional soft etch may be performed. The soft etch may be used to remove any native oxide on top of the first amorphous/poly layer. In addition, the soft etch may be tailored to roughen the surface of the first amorphous/poly layer to improve the adhesion of the second amorphous/poly layer. Next, another step of heating may then be performed (step 1650) to achieve further crystallization after deposition of this second amorphous/ploy layer. Again, such crystallization may be achieved via any of the heating and/or laser application processes set forth herein. According to one or more exemplary implementations, here, this material may be heated via a laser having a wavelength between about 266 nm and about 2 μm. Further, in some implementations, the laser may be within or near to the infrared wavelengths, the laser may have a wavelength between about 800 nm and about 1600 nm, have a wavelength of about 880 nm, or have a wavelength of about 1.06 μm. Finally, a step of providing N-type and P-type doped regions in the layer as well as electrical contacts over these regions (step 1660) may then be performed, as set forth in more detail above. Here, the doped regions may be created first, with the contacts being provided afterwards via a separate process, or the dopants may be provided on/along with the contacts and infused into the layer via a subsequent heating process. Further, as an optional process, an initial step of coating the substrate with an anti-reflective coating (step 1510) may be performed prior to the placement and heating of the silicon materials on the substrate, as set forth in more detail above in association with FIGS. 15A and 15B.

In exemplary implementations of the solar cell architecture and innovations described above, the silicon-containing layer may be crystallized using heating/laser step(s), including sub-melt and other features set forth in the related applications incorporated by reference herein. In addition, the crystallization step(s) may also use a seed layer as described in detail below and in FIGS. 17A through 25B.

FIG. 17A illustrates an exemplary method of crystallizing silicon/silicon-based materials on a substrate, consistent with aspects of the innovations herein. As shown in FIG. 17A, a silicon-containing seed layer may be placed on a substrate, such as glass (step 1710). This crystalline silicon-containing seed layer may be placed on top of the substrate, as shown above, or it may be placed on top of another layer such as an anti-reflective coating, as explained in more detail below. Here, the seed layer may also be bonded to the substrate or other layer by means of electrostatic bonding. The seed layer may also be placed by mechanical means, such as vacuum. In other implementations, either hydrophilic or hydrophobic bonding may be used. In some implementations, bonding using a laser or other heat source may be used. In some exemplary implementations, the seed layer may be about 50 nm to about 100 micrometers, in other exemplary implementations about 200 nm to about 600 nm, and in still other exemplary implementation, about 350 or about 355 nm. Next, in step 720, the seed layer may be covered with an amorphous/poly material, such as amorphous/poly silicon or another amorphous/poly silicon-based material. Other amorphous/poly silicon containing materials include SiGe (silicon-germanium) or SiC (silicon carbide) or SiGeC (silicon-germanium-carbide). In some implementations, the silicon containing amorphous/poly material may have intentional incorporation of deuterium or fluorine. In some exemplary implementations, the amorphous/poly material may be deposited via depositions processes such as CVD or PECVD (plasma enhanced chemical vapor deposition), via sputtering processes, or other known processes of depositing such layer(s). Here, for example, an amorphous/poly layer having a thickness of about 20 nm to about 1000 nm may be deposited over the seed layer. In further exemplary implementations, a layer of about 30 nm to about 60 nm may be deposited on the seed layer, and in still further exemplary implementations, a layer of about 45 nm may be deposited. Additionally, in step 1730, the seed layer and amorphous/poly material may be heated to transform these materials into crystalline form. Here, for example, these materials may be heated by conventional heating mechanisms used, such as strip heaters or lamps, and/or they may be heated via lasers to crystallize the material, such as via the sub-melt laser anneal processes set forth above or the laser crystallization processes set forth below. In some implementations using lamps, the lamps may be configured in the form of a line source focused on the material. In some exemplary implementations, a laser of wavelength between about 266 nm and about 2 micrometers may be applied to the materials to transform them into crystalline form. In other exemplary implementations, lasers of wavelengths from about 400 nm to about 700 nm may be used, lasers of green wavelength may be used, lasers of ultraviolet wavelength may be used, and/or in still further exemplary implementations, a laser having a wavelength of about 532 nm or about 515 nm may be used.

In general, the laser anneal processes herein may be optimized to grow the crystal vertically on top of the seed layer, and may also be applied to grow the crystal laterally on the side of the seed layer. According to exemplary implementations of the present innovations, the lasers used herein may utilize different settings such as power, pulse energy, scan speed, and spot size (e.g., on top of the seed layer, etc.), and/or different settings or even different lasers when being irradiated on the sides of the seed layers.

FIG. 17B illustrates an exemplary method of crystallizing silicon/silicon-based materials on a substrate, consistent with aspects of the innovations herein. FIG. 17B illustrates an alternate implementation of the innovations herein involving similar steps of FIG. 17A, although with the order of placing the amorphous/poly material and seed layer on the substrate reversed. In other words, in FIG. 17B, the substrate is first covered, in step 1740 with the amorphous/poly material. Then, in step 1750, a silicon-containing seed layer or material is placed on top of the amorphous/poly material. The processes and materials used, here, may be similar to those set forth in connection with FIG. 17A above. Lastly, once the amorphous/poly material and seed layer are in place, these materials are heated (step 1730) using techniques consistent with those set forth above in connection with FIG. 17A. In some implementations of the techniques shown in FIG. 17A or FIG. 17B, the laser source may be through the glass. In other implementations, the laser source may be directly incident on the material and seed from the top.

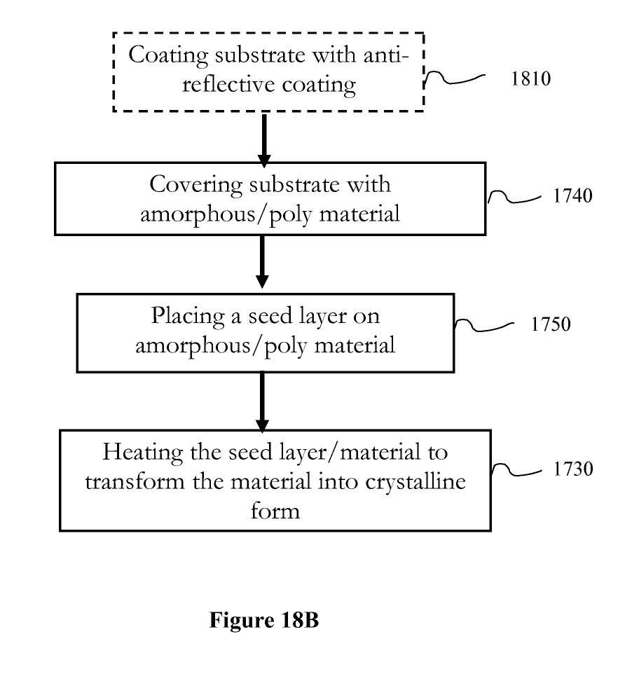

FIG. 18A illustrates another exemplary implementation of the innovations of FIG. 17A although including a step of initially coating the substrate with an anti-reflective coating (step 1810) prior to placement of the seed and amorphous/poly material layers thereon. Here, for example, a silicon based antireflective layer such as SiN, SiO₂, SiON, etc., may be first deposited on the substrate, prior to placement and processing of the remaining layers. In some exemplary implementations, a SiN, SiO₂ or SiON coating having a thickness of about 50 nm to about 250 nm may be deposited. In other exemplary implementations, such a coating of about 65 nm to about 95 nm in thickness may be used, and in still a further exemplary implementation, a coating of about 75 nm in thickness may be used. The anti-reflective coating layer may also be composed of more than one material, such as, for example a SiN layer applied in connection with an SiO₂ layer. According to one exemplary implementation, the SiN layer may be of about 75 nm thick and the SiO₂ layer may be about 20 nm thick. Further, a layer of this nature, such as a SiO₂ layer, may serve as a stress-relief layer. In alternate implementations, such materials of thickness in a range of about 120 nm to about 180 nm, or of about 150 nm, may be used, such as with SiN layers. Consistent with other aspects of the innovations herein, SiO₂ layers having thickness in ranges between about 0 (little or no layer) through about 200 nm, between about 10 nm to about 30 nm, or of about 20 nm may be used. Next, the steps of placing a silicon-containing seed layer on the substrate (710), covering the seed layer with amorphous/poly material (720), and heating the seed layer/material to transform the material into crystalline form (1730), as with FIG. 17A, may be performed on top of the anti-reflective coating.

FIG. 18B illustrates another exemplary implementation of the innovations of FIG. 17B although including a step of initially coating the substrate with an anti-reflective coating (step 1810) prior to placement of the amorphous/poly material and seed layers thereon. Anti-reflective coatings consistent with those set forth above in connection with FIG. 18A may be used. Further, after the anti-reflective coating is applied, the steps of covering with amorphous/poly material (1740), placing a silicon-containing seed layer on the amorphous/poly material (1750), and heating the seed layer/material to transform the material into crystalline form (1730) may be performed on top of the anti-reflective coating.

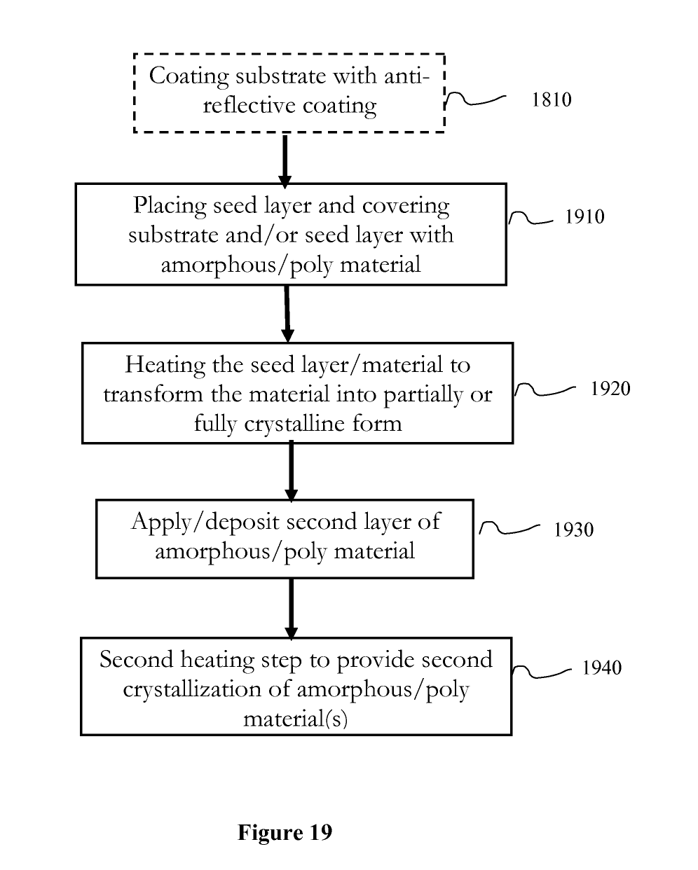

FIG. 19 illustrates another exemplary method of crystallizing silicon/silicon-based materials on a substrate, consistent with aspects of the innovations herein. Referring to FIG. 19, an initial step of applying seed and amorphous/poly layers is performed (step 1910) Here, for example, the seed layer may be applied first with the amorphous/poly material on top as explained in connection with FIG. 17A, or the amorphous/poly material may be applied first as explained in connection with FIG. 17B. Next, a step of heating the seed layer and the amorphous/poly material (step 1920) is performed, until the material is transformed into partially or fully crystalline form. Here, for example, this heating step may comprise any of the heating and/or laser application techniques set forth herein. Another step of applying a second layer of amorphous/poly material is then performed (step 1930). Here, according to one or more exemplary implementations, a second amorphous/poly layer, such as a layer of amorphous silicon, having a thickness of about 50 nm to about 30 μm may be deposited. For example, a second amorphous/poly layer of between about 1 μm to about 8 μm may be deposited. According to some exemplary implementations, a second amorphous/poly layer of about 4 μm may be deposited. Further, prior to deposition of the second amorphous/poly layer, an optional soft etch may be performed. The soft etch may be used to remove any native oxide on top of the first amorphous/poly layer. In addition, the soft etch may be tailored to roughen the surface of the first amorphous/poly layer to improve the adhesion of the second amorphous/poly layer. Finally, another step of heating may then be performed (step 1940) to achieve further crystallization after deposition of this second amorphous/ploy layer. Again, such crystallization may be achieved via any of the heating and/or laser application processes set forth herein. According to one or more exemplary implementations, here, this material may be heated via a laser having a wavelength between about 266 nm and about 2 μm. Further, in some implementations, the laser may be within or near to the infrared wavelengths, the laser may have a wavelength between about 800 nm and about 1600 nm, have a wavelength of about 880 nm, or have a wavelength of about 1.06 μm. Further, as an optional process, an initial step of coating the substrate with an anti-reflective coating (step 1810) may be performed prior to the placement and heating of the silicon materials on the substrate, as set forth in more detail above in association with FIGS. 18A and 18B.

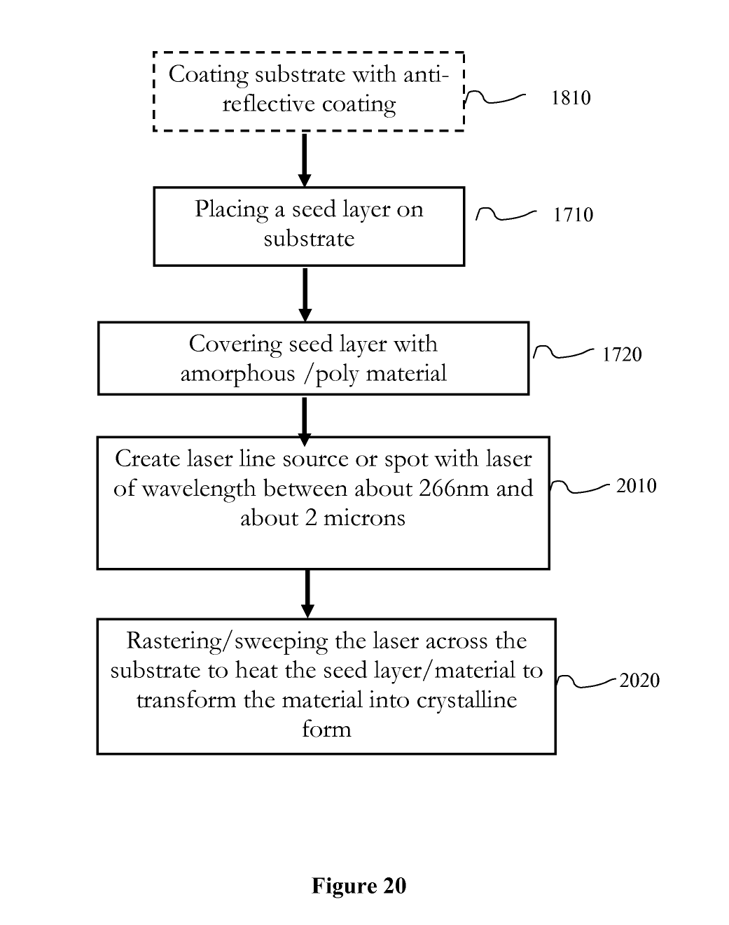

FIG. 20 illustrates a further exemplary method of crystallizing silicon/silicon-based materials on substrate(s), consistent with aspects of the innovations herein. FIG. 20 illustrates an exemplary method of crystallization comprising initial steps (steps 1710 and 1720) related to placement of materials on a substrate as well as heating steps (steps 2010 and 2020) related to crystallizing the materials upon a substrate. This exemplary method begins with steps of placing a silicon-containing seed layer on substrate 1710, and covering the seed layer with amorphous/poly material 1720, as set forth in more detail in connection with FIGS. 17A and 17B, above. These steps (steps 1710 and 1720) may also be done in the reverse order, as explained above in connection with FIGS. 18A and 18B. With regard to the exemplary heating/crystallization steps, here, a step of creating a laser line or spot source with a laser of a wavelength between about 266 nm and about 2 μm (step 2010) may be performed. Here, the laser may be focused on the seed/material from above, or through the substrate (if mostly transparent to the wavelength chosen). Next, one or more steps of rastering and/or sweeping the laser across the substrate (step 2020) are performed. In some exemplary implementations, the laser may first be focused on/over the seed layer and then swept across the substrate to crystallize the deposited material. Here, such rastering or sweeping may be performed in 2 or more steps and/or directions. For example, the laser may be applied using one or more X-direction scans and/or one or more Y-direction scans, whereby the seed layer/amorphous-poly material is heated to transform it into crystalline form. Further, as an optional process, an initial step of coating the substrate with an anti-reflective coating (step 1810) may be performed prior to the placement and heating of the silicon materials on the substrate, as set forth in more detail above in association with FIGS. 18A and 18B.

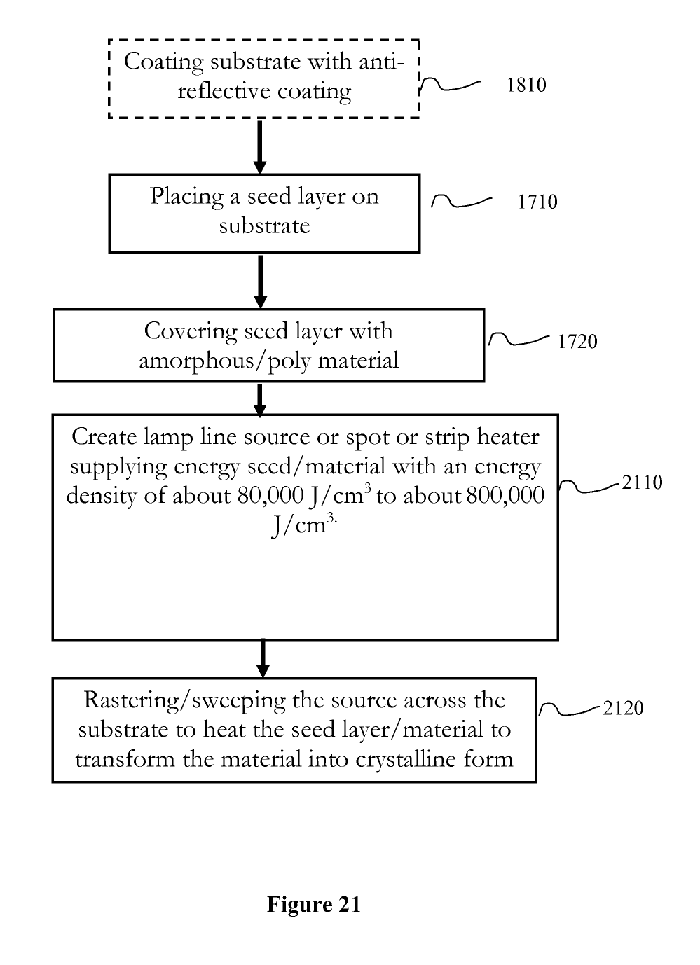

FIG. 21 illustrates yet another exemplary method of crystallizing silicon/silicon-based materials on substrate(s), consistent with aspects of the innovations herein. FIG. 21 illustrates an exemplary method of crystallization comprising initial steps (steps 1710 and 1720) related to placement of materials on a substrate as well as heating steps (steps 2110 and 2120) related to crystallizing the materials upon a substrate. This exemplary method begins with steps of placing a silicon-containing seed layer on substrate 1710, and covering the seed layer with amorphous/poly material 1720, as set forth in more detail in connection with FIGS. 17A and 17B, above. These steps (steps 1710 and 1720) may also be done in the reverse order, as explained above in connection with FIGS. 18A and 18B. With regard to the exemplary heating/crystallization steps, here, a step of applying energy (step 2110) such as heat energy to the seed layer/amorphous-poly material is then performed. Such energy may be applied by a lamp line source, one or more spot heaters, one or more strip heaters, other known heating devices used in semiconductor, thin film or flat panel processing, and/or via any of the laser applications set forth herein. In some exemplary implementations, here, energy such as heat energy having energy densities between about 80,000 J/cm³ to about 800,000 J/cm³, or between about 200,000 J/cm³ to about 550,000 J/cm³, or between about 400,000 J/cm³ to about 450,000 J/cm³ may be applied with regard to silicon layers, here. According to other implementations, energies of specific quantities may be applied as a function of the melting point, composition, physics, and/or thickness of the amorphous/poly material. By way of example, here, for amorphous silicon, energy of between about 400 mJ/cm² and about 4000 mJ/cm² for a silicon material thickness of about 50 nm may be applied. Moreover, absent other parameter changes, materials other than such pure silicon will require correspondingly commensurate levels of energy to achieve crystallization as a function of their physics, physical response to the energy being applied, and melting point. According to some exemplary implementations using a lamp or strip heater, the heat source is stepped and repeated, i.e., one area of the amorphous/poly material is heated and then either the heat source or the substrate is moved/stepped so the heat source is applied to the next area, and so on. In this fashion the amorphous/poly material on the entire area of the substrate may be crystallized. Next, for processes in which such energy is being applied via a movable source, one or more steps of rastering and/or sweeping the source across the substrate (step 2120) are performed. In some exemplary implementations, the laser may first be focused on/over the seed layer and then swept across the substrate to crystallize the deposited material. Here, such rastering or sweeping may be performed in 2 or more steps and/or directions. For example, the laser may be applied using one or more X-direction scans and/or one or more Y-direction scans, whereby the seed layer/amorphous-poly material is heated to transform it into crystalline form. Further, as an optional process, an initial step of coating the substrate with an anti-reflective coating (step 1810) may be performed prior to the placement and heating of the silicon materials on the substrate, as set forth in more detail above in association with FIGS. 18A and 18B.

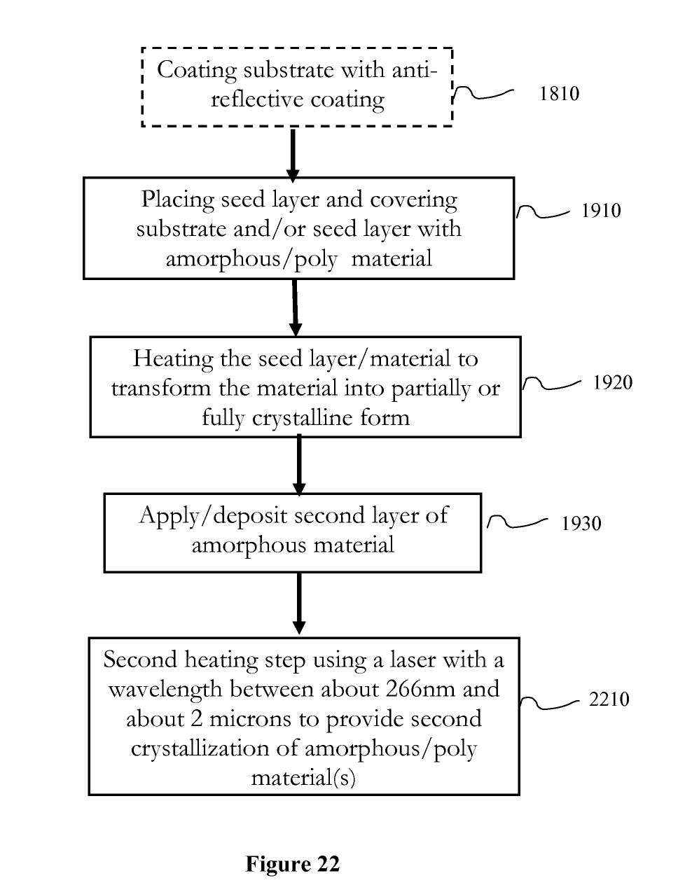

Referring to FIG. 22, another exemplary method of crystallizing amorphous/poly materials on substrate(s), consistent with aspects of the innovations herein, is shown. FIG. 23 illustrates an initial series of steps, steps 1910, 1920 and 1230, consistent with FIG. 19. Specifically, initial steps of placing the seed layer and amorphous/poly material on the substrate 1910 (in any order), heating the seed layer/amorphous-poly material 1920 into crystalline or partially crystalline form, and covering the crystallized material with a second layer of amorphous/poly material 930 may be performed. Next, in the exemplary implementation illustrated, this second layer of amorphous/poly material may be heated via a laser having a wavelength between about 266 nm and about 2 μm, wherein such lasers may be applied from above the substrate, or from below the substrate (for substrates that are mostly transparent to the wavelength used), with additional details of exemplary application of such lasers are set forth further below. Further, as another optional process, an initial step of coating the substrate with an anti-reflective coating (step 1810) may be performed prior to the placement and heating of the silicon materials on the substrate, as set forth in more detail above in association with FIGS. 18A and 18B.

FIG. 23 illustrates still another exemplary method of crystallizing silicon/silicon-based materials on substrate(s), consistent with aspects of the innovations herein. Referring to FIG. 23, an exemplary crystallization process including steps of doping the amorphous/poly material and covering the crystallized material with one or more metallization layers is disclosed. FIG. 23 also illustrates an initial series of steps, steps 1910 and 1910, consistent with FIG. 19. Specifically, initial steps of placing the seed layer and amorphous/poly material on the substrate 910 (in any order), and heating the seed layer/amorphous-poly material 1920 into crystalline or partially crystalline form may be performed. Next, a step of doping the amorphous/poly material 1310 may optionally be performed. Here, for example, N and P dopants may be incorporated into the silicon or silicon-containing material for purpose of fabricating transistor or solar cell structures in such substrates. N and P dopants may be added before (2310A) or after (2310B) the crystallization of the amorphous/poly layer. Further, in certain implementations, addition of one of the dopants may be skipped entirely, such as the P-type dopant (Boron). According to some exemplary implementations, dopants may be added using a dopant paste and application of a laser on the regions where the dopants are to be incorporated. Other methods of dopant incorporation may be used in some implementations, including deposition of doped layers, such as a doped silicon layer. Additionally, an optional step of metallization 2320 may also be performed. In some implementations, for example, a dielectric layer such as silicon dioxide (SiO2) or silicon nitride (SiN) may be added. Here, the thickness of such layers may be between about 20 nm and about 20 μm, preferably about 500 nm (0.5 μm). Further, exemplary metallization layers Aluminum, Silver, other compositions including one or both of these metals, or other metal materials known in the art for use on thin film structures. Lastly, as another optional process, an initial step of coating the substrate with an anti-reflective coating (step 1810) may be performed prior to the placement and heating of the silicon materials on the substrate, as set forth in more detail above in association with FIGS. 18A and 18B.

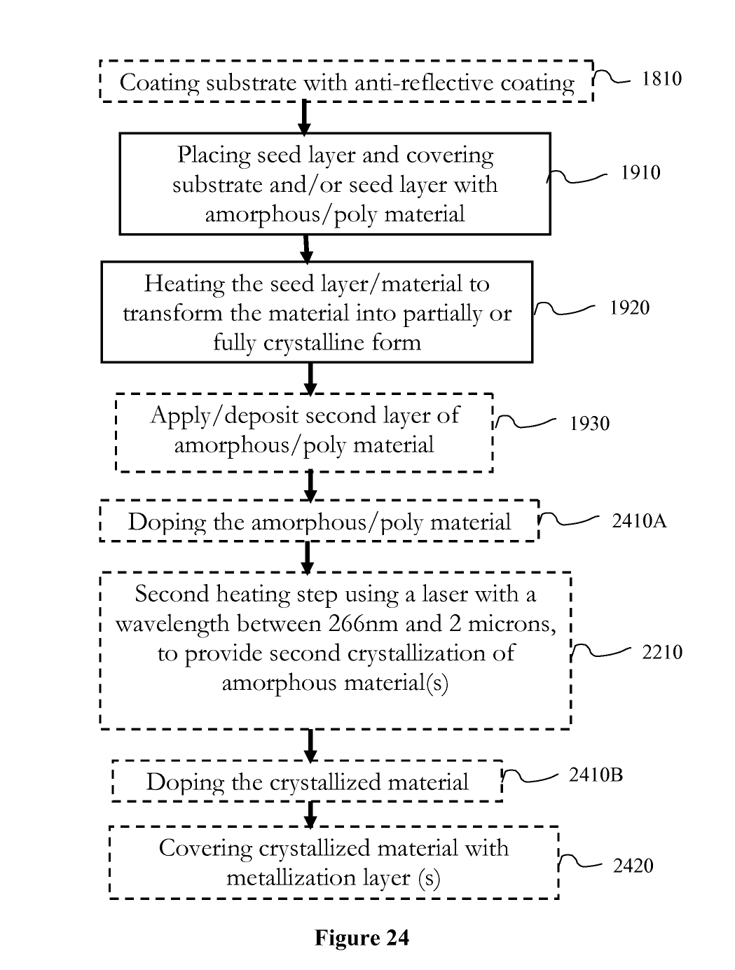

FIG. 24 illustrates yet another exemplary method of crystallizing silicon/silicon-based materials on substrate(s), consistent with aspects of the innovations herein. Referring to FIG. 24, an exemplary process including steps of doping the amorphous/poly material and covering the crystallized material with one or more metallization layers is disclosed. FIG. 24 also illustrates an initial series of steps, steps 1910, 1920 and 1930, consistent with FIG. 19. Specifically, initial steps of placing the seed layer and amorphous/poly material on the substrate 1910 (in any order), heating the seed layer/amorphous-poly material into crystalline or partially crystalline form 1920, and applying/depositing a second amorphous/poly layer 1930, may be performed. However, in FIG. 24, the step of coating/depositing a second layer of amorphous/poly material, step 1930, is shown as an optional step because, in some implementations of the innovations herein, the later doping and/or metallization processes are performed in fabricating devices that have only a single layer of amorphous/poly material. Further, one or more doping steps (steps 2410A and 2410B) may also be optionally performed. Again, N and P dopants may be incorporated into the silicon or silicon-containing material for purpose of fabricating transistor or solar cell structures in such substrates. Methods including application/deposition of a second amorphous/poly layer may also include a second heating step, 2310, as set forth herein. Here, then, N and/or P dopants may be added before this heating/crystallization, step 2410A, or such dopants may be added after the heating step, to the crystallized material, step 2410B. Further, in certain implementations, addition of one of the dopants may be skipped entirely, such as the P-type dopant (Boron). And again, dopants in some implementations may be added using a dopant paste and application of a laser on the regions where the dopants are to be incorporated. Furthermore, an optional step of metallization 2320 may also be performed. In some implementations, for example, a dielectric layer such as silicon dioxide (SiO2) or silicon nitride (SiN) may be added. Here, the thickness of such layers may be between about 20 nm and about 20 μm, preferably about 500 nm (0.5 μm). Further, exemplary metallization layers Aluminum, Silver, other compositions including one or both of these metals, or other metal materials known in the art for use on thin film structures. Lastly, as another optional process, an initial step of coating the substrate with an anti-reflective coating (step 1810) may be performed prior to the placement and heating of the silicon materials on the substrate, as set forth in more detail above in association with FIGS. 18A and 18B.

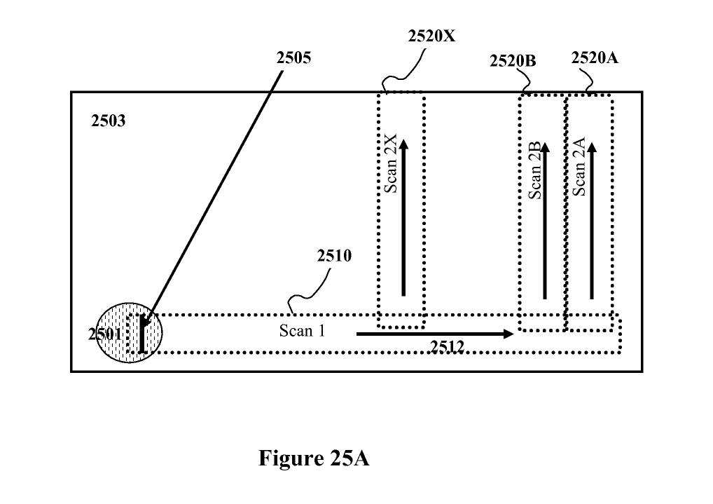

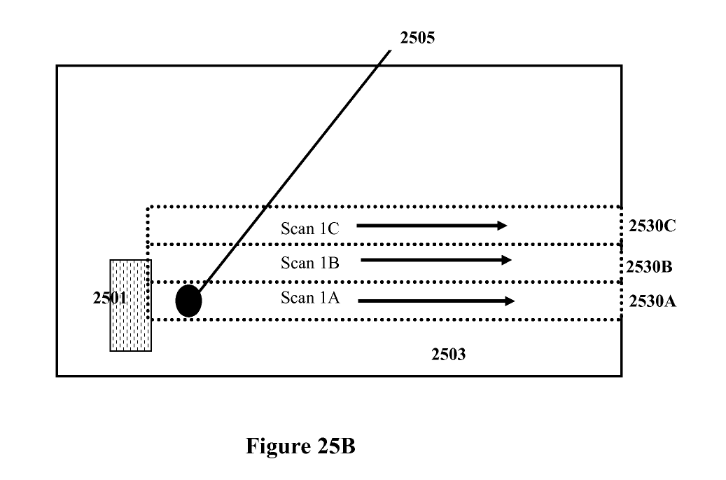

Referring to FIGS. 25A and 25B, exemplary methods of rastering or scanning of lasers over substrates, consistent with aspects of the innovations herein, are shown. FIGS. 25A and 25B are top view diagrams illustrating a base material 2503 to be crystallized (e.g., glass, etc.), a seed layer 2501, and a laser source 2505, which is shown as a line source though could also be, e.g., a spot source. Here, although depicted in one shape, the seed regions may be square, rectangular, circular, or other known shapes used for such seed region. Additionally, exemplary lasers/line sources used consistent with the innovations herein may include, with regard to the long axis, lasers with lines sources of between about 10 mm to about 500 mm, of between about 20 mm to about 80 mm, of about 80 mm, or of about 20 mm. Further, such line sources along the long axis may be “flat top” sources where the intensity is constant along the long axis. With regard to the short axis, lasers with line sources between about 3 μM and about 100 μm, between about 5 μm and about 50 μm, of about 5 μm, or of about 20 μm. Further, along the short axis, the line sources used may be of standard Gaussian profiles (i.e., the intensity is not flat) although flat profiles may also be used.

Turning to the crystallization techniques shown in FIG. 25A, a first scan 2510 may be performed to crystallize a first zone 2512 along the length of the glass. Next, a series of subsequent scans (2520A, 2520B . . . 2520x) may be performed to propagate crystal over the entire glass sheet. Here, the quantity of scans needed may vary as a function of length of the laser line source. For example, with regard to a 1.3 m (1300 mm) substrate, given a line source of 20 mm, one must perform at least 65 scans to cover the entire glass.

Referring to the crystallization technique shown in FIG. 25B, a process for crystallizing amorphous/poly materials is disclosed. Here, for example, this technique is well suited for subsequent layers of amorphous/poly material, e.g., when an underlying (first) layer has already been crystallized or partially crystallized. (In such instances, it is not necessary to start the rastering or scanning at/over the seed layer, although this may certainly be done in some implementations.) According to one exemplary implementation, the laser source 2505 may be a spot source with a spot size of between about 10 μm to about 750 μm in diameter, or between about 200 μM and about 300 μm, or of about 250 μm. Finally, if the underlying layer has been adequately crystallized, the laser spot may simply be rastered across the whole substrate.

In accordance with innovations herein, among many other specific advantages, temporal requirements for processing silicon wafer on substrates such glass may be reduced from 3-4 hours at 550° C. to less than 45 minutes. This may reduce the cycle time of the process as well as the cost. As such, systems and methods herein may be used to realize lower cost semiconductors and solar cells. Innovative systems and methods may also be applied to save cost and cycle time in preparing silicon-on-glass substrates for the production of flat panel displays.

As such, especially in the case of solar cell fabrication, the methods herein may readily enables a continuous production line, as most other steps are less than 10 minutes long. Accordingly, features imparting such improved processing times are especially innovative as drawbacks of having time-consuming processing steps (4 hours, etc.) include the need for large amounts of inventory and storage, especially before and after lengthy anneal steps. These drawbacks significantly increase the cost and complexity of a solar cell manufacturing line. Moreover, various implementations of the innovations herein entail only about 15 minutes and hence perfectly integrate with continuous, low-cost solar cell production lines.

Turning to some specific applications, namely solar cell applications, use of the innovations herein with a SiGe (silicon-germanium) wafer, piece or layer, rather than pure silicon material, increases the light absorption in the infrared region, thereby increasing the efficiency of solar cells. In one exemplary implementation, a silicon-germanium layer is used for the solar cell. For certain implementations, the ratio of silicon to germanium may be more than 80%. In other implementations, the ratio of silicon to germanium may be 90%/10%, respectively. In still further implementations, the germanium may comprise only between about 2% and about 5%. Here, a silicon-germanium layer on top of a substrate such as glass may be crystallized as described above.

In still further exemplary implementations of the systems, methods and products herein, silicon wafer bonding and cleaving innovations are used with other substrates such as plastic or stainless steel instead of silicon/glass. The use of plastic substrates along with these innovations enables low cost flexible solar cells which can be integrated more easily with, e.g., buildings. One exemplary use of plastic substrates with the innovations herein includes integrating solar cells with windows of commercial buildings (also known as BIPV or Building-integrated-photovoltaics).

Further, aspects of the innovations herein may include coating layers either on the outside of the glass layer, or in between the glass and the silicon layer to be cleaved, or both sides. According to the certain innovations, for example, the silicon-based layer may also be other semiconductor materials such as SiGe (silicon-germanium) or SiC (silicon-carbide). For solar cell applications in particular, use of the innovations herein with SiGe (silicon-germanium) increases the light absorption in the infrared region and thus increases the efficiency of solar cells. In one exemplary implementation, a silicon-germanium layer with the silicon-germanium ratios listed above (>80%/<20% or ˜90%/˜10%), or of about 2 to about 5% germanium may be used for the solar cell. The silicon-germanium layer on top of the glass substrate may be bonded with the silicon wafer as described above.

Aspects of the innovations herein may also include one or more of the features, functionality and/or processing steps set forth in related application Ser. No. 12/842,996, filed Jul. 23, 2010, published as US2011/0089429A1, now patent Ser. No. ______, No. 12/857,549, filed Aug. 16, 2010, published as US2011/0089420A1, now patent Ser. No. ______, No. 12/954,837, filed Nov. 26, 2010, published as US2011/0165721A1, now patent Ser. No. ______, and Ser. No. 13/160,476, filed Jun. 14, 2011, published as US201______A1, now patent Ser. No. ______, which are incorporated herein by reference in entirety.

As set forth herein, various methods of producing composite solar cell structures composed of a silicon-containing material bonded to a substrate are disclosed. According to some illustrative implementations, exemplary methods may comprise engaging the silicon-containing piece into contact with a surface of the substrate, wherein the substrate includes one or more SiN/SiO2/Si-containing layer(s)/coating(s) on the surface, and irradiating/treating the silicon-containing piece with a laser having a wavelength of between about 350 nm to about 1070 nm, such that complete bonding between the piece and the glass substrate is achieved without need for further anneal. Further, the methods may include any of the other features set forth herein. Additionally, the innovations herein may of course be part of other processes associated with fabrication of the subject elements (e.g., solar panels, thin film solar cells, flat panel displays, etc.), such as set forth in U.S. patent application Ser. No. 12/845,691, filed Jul. 28, 2010, published as US2011/0101364A1, now patent Ser. No. ______, incorporated herein by reference in entirety, i.e., the features shown in FIGS. 1-16 and the associated written description thereof.

As such, in accordance with innovations herein, temporal requirements for the bonding and cleaving of the silicon wafer on glass may be reduced from 3-4 hours at 550° C. to less than 45 minutes. This may reduce the cycle time of the process as well as the cost. As such, systems and methods herein may be used to realize lower cost semiconductors and solar cells. Innovative systems and methods may also be applied to save cost and cycle time in preparing silicon-on-glass substrates for the production of flat panel displays.

Flat Panel Display/Other Embodiments

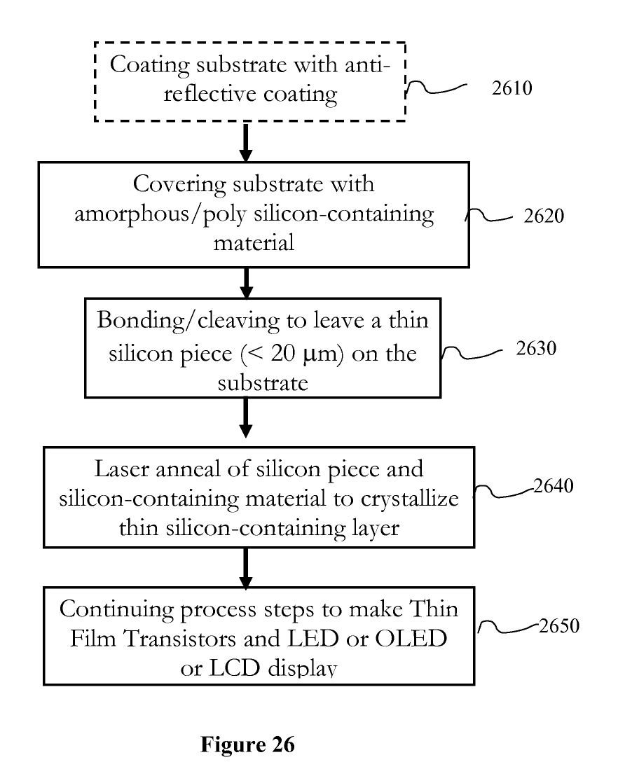

FIG. 26 illustrates yet another exemplary method including crystallization of silicon/silicon-based materials on a substrate, consistent with aspects of the innovations herein. Referring to FIG. 26, an exemplary process including one or more steps related to fabrication of flat panel (LED, OLED, LCD, etc.) displays and/or thin film transistors is disclosed. FIG. 12 illustrates an initial series of steps, steps 2610 and 2620. Specifically, initial steps of placing the SiN/SiO2/Si-containing layer or layers, such as a SiN, SiO₂, SiON etc. layers and/or amorphous/poly Si layer(s), on the substrate 2610 and 2620 (in any order) are shown. Bonding and cleaving a silicon wafer or piece consistent with the innovations described herein is shown as step 2630. Heating the seed layer/amorphous-poly material 2640 into crystalline or partially crystalline form may be performed, such as via use of a laser. Next, in 2650, one or more further processing steps related to making thin film transistors and/or flat panel (LED, OLED, LCD, etc.) displays may be performed.

Here, in such flat panel display embodiments, the SiN/Si02/Si-containing coating(s)/layer(s) may be comprised of one or more of the materials set forth above. Further, another illustrative flat panel display fabrication process may involve a single layer/coating comprising Si (amorphous silicon or poly silicon) in thickness ranges of between about 1 nm and about 100 nm, between about 20 nm and about 75 nm, or between about 40 nm and about 50 nm, or of about 45 nm. Here, for example, such layer may be deposited by PECVD using SiH4. In these flat panel display and thin film transistor embodiments, the substrate may be comprised of materials used to fabricate the subject device, such as e.g. aluminosilicate glass.

Other aspects of the innovations herein will be apparent to those skilled in the art from consideration of the specification and practice of the innovations herein. It is intended that the specification and examples be considered as exemplary only, with a true scope and spirit of the inventions being defined by the scope of the claims as per the totality of the disclosure in combination with the relevant knowledge of an ordinary artisan.

1. A method of fabricating a device having one or both of backside and/or front side contacts, the device including a substrate and a first layer of silicon containing material, the method comprising:
performing a first heating step of the first layer to transform the silicon containing material into crystalline form;
providing a second layer to the device over the crystalline material of the first layer, the second layer including amorphous/poly silicon; and
performing a second heating step of the device to crystallize the second layer.

2. (canceled)

3. The method of claim 1 wherein the second heating step comprises using a laser with a wavelength of between about 266 nm and about 2 microns to heat the second layer.

4. The method of claim 3 wherein the laser is transmitted through the substrate to heat the second layer.

5. The method of claim 3 wherein the laser is applied to the second layer from a top direction, above the second layer away from the substrate.

6. (canceled)

7. The method of claim 1 further comprising providing a seed layer in association with the substrate and the first layer, wherein the seed layer and the first layer are heated in the first heating step.

8. The method of claim 1 wherein the first heating step comprises applying laser energy of a wavelength of between about 266 nm and about 2 microns to heat the first layer or to heat the first layer and an associated seed layer.

9. The method of claim 8 wherein the laser energy is applied through the substrate to heat the first layer.

10.-11. (canceled)

12. The method of claim 1 wherein the device is initially provided with an anti-reflective coating, between the substrate and the first layer, prior to the first heating step.

13. The method of claim 1 wherein the first layer has a thickness of between about 25 nm and about 200 nm.

14. The method of claim 1 wherein the second layer has a thickness of between about 500 nm and about 10 microns.

15. The method of claim 1 further comprising incorporating N-type and/or P-type dopants into one or more regions of the device and/or the crystallized second layer.

16. The method of claim 15 wherein the N-type and/or P-type dopants are incorporated into one or more backside regions of the device, along a top surface of the crystallized second layer.

17. The method of claim 1 further comprising providing metallization and/or conductive elements/traces to make electrical contact with one or more areas of the device and/or the crystallized second layer.

18. (canceled)

19. A method of fabricating a device, comprising:
placing an amorphous/poly material layer on a base substrate;
placing a seed layer on the amorphous/poly layer; and
heating the seed layer/material to transform the material into crystalline form.

20. The method of claim 1 further comprising a seed layer that is a crystalline silicon material.

21. The method of claim 1 further comprising coating the base substrate with an anti-reflective coating before placing the seed layer thereon.

22. (canceled)

23. The method of claim 20 wherein the seed layer has a thickness of about 50 nm to about 100 microns.

24.-25. (canceled)

26. The method of claim 1 wherein the base substrate is covered by the amorphous/poly material having a thickness of about 20 nm to about 1000 nm.

27.-28. (canceled)

29. The method of claim 1 herein wherein the base substrate is a material selected from the group of glass, plastic or steel.

30.-43. (canceled)

44. A thin film device, produced by the process of:
placing an amorphous/poly material layer on a base substrate;
heating the material to transform the material into crystalline form.

45.-114. (canceled)
